(19) United States
(12) Patent Application Publication
(10) Pub. No.: US 2024/0213195 A1
(43) Pub. Date: Jun. 27, 2024

(54) SEMICONDUCTOR STRUCTURE WITH HYBRID BONDING AND METHOD FOR MANUFACTURING THE SAME

(71) Applicant: TAIWAN SEMICONDUCTOR MANUFACTURING COMPANY, LTD., Hsinchu (TW)

(72) Inventors: Wei-De HO, Hsinchu (TW); Wei-Xiang YOU, Hsinchu (TW); Jui-Chien HUANG, Hsinchu (TW); Szuya LIAO, Hsinchu (TW)

(73) Assignee: TAIWAN SEMICONDUCTOR MANUFACTURING COMPANY, LTD., Hsinchu (TW)

(21) Appl. No.: 18/174,046

(22) Filed: Feb. 24, 2023

Related U.S. Application Data
(60) Provisional application No. 63/434,287, filed on Dec. 21, 2022.

(51) Int. Cl. H01L 23/00; H01L 23/522; H01L 25/065; H01L 25/07; H01L 27/088

(52) U.S. Cl. CPC H01L 24/08; H01L 23/5226; H01L 24/05; H01L 24/80; H01L 25/0657; H01L 25/074; H01L 27/088; H01L 2224/05553; H01L 2224/05554; H01L 2224/05571; H01L 2224/05624; H01L 2224/05647; H01L 2224/05655; H01L 2224/05657; H01L 2224/05664; H01L 2224/05669; H01L 2224/05676; H01L 2224/05684; H01L 2224/08145; H01L 2224/80357; H01L 2224/80379; H01L 2224/80896; H01L 2225/06541; H01L 2924/04642; H01L 2924/0504; H01L 2924/0544; H01L 2924/059

(57) ABSTRACT

A semiconductor structure includes a first device assembly and a second device assembly. Each of the first and second device assembly includes a substrate, a main unit disposed on the substrate and including at least one device, a dielectric unit disposed on the main unit and having an interconnecting surface opposite to the substrate, and an electrically conductive routing disposed in the dielectric unit, electrically connected to the at least one device, and including an end portion. The interconnecting surface of the dielectric unit of the first device assembly is bonded to the interconnecting surface of the dielectric unit of the second device assembly such that the end portion of the electrically conductive routing of the first device assembly is in direct contact with the end portion of the electrically conductive routing of the second device assembly. A method for manufacturing the semiconductor structure are also disclosed.

### REFERENCE TO RELATED APPLICATION

This application claims priority of U.S. Provisional Patent Application No. 63/434,287, filed on Dec. 21, 2022, the contents of which is incorporated herein by reference in its entirety.

### BACKGROUND

Transistors are key active components in modern integrated circuits (ICs). With rapid development of semiconductor technology, critical dimension (CD) of transistors keeps shrinking and various three-dimensional (3D) transistor structures are springing up, making it possible to integrate a large number of transistors per unit area. In addition to devices (such as transistors, capacitors, resistors, etc.) fabricated in a front end of line (FEOL), interconnects (such as wires, vias, etc.) fabricated in a back end of line (BEOL) need a predetermined space for wiring. Till date, advanced node transistors, as well as interconnects which interconnect the transistors are under continuous development, so as to achieve ICs with a high integration density.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 are two different schematic sectional views illustrating a semiconductor structure in accordance with some embodiments.

FIGS. 3 to 5 are schematic plane views respectively illustrating a middle electrically conductive feature, a first electrically conductive feature, and a second electrically conductive feature of the semiconductor structure in accordance with some embodiments.

FIGS. 6 and 7 are two different schematic sectional views illustrating another semiconductor structure in accordance with some embodiments.

FIGS. 8 and 9 are schematic plane views respectively illustrating a middle electrically conductive feature and a second electrically conductive feature of the another semiconductor structure in accordance with some embodiments.

FIG. 10 is a schematic view illustrating an electrical connection between first and second devices of the another semiconductor structure in accordance with some embodiments.

FIG. 11 is a schematic view illustrating another electrical connection between first and second devices of a reference semiconductor structure in accordance with some embodiments.

FIGS. 12 to 14 are schematic sectional views respectively illustrating three different semiconductor structures each having dummy portions in accordance with some embodiments.

FIGS. 15 to 18 are schematic sectional views respectively illustrating four different modified semiconductor structures in accordance with some embodiments.

FIG. 19 is a flow diagram illustrating a method for manufacturing a semiconductor structure in accordance with some embodiments.

FIGS. 20 to 22 are schematic views respectively illustrating intermediate stages of the method depicted in FIG. 19 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

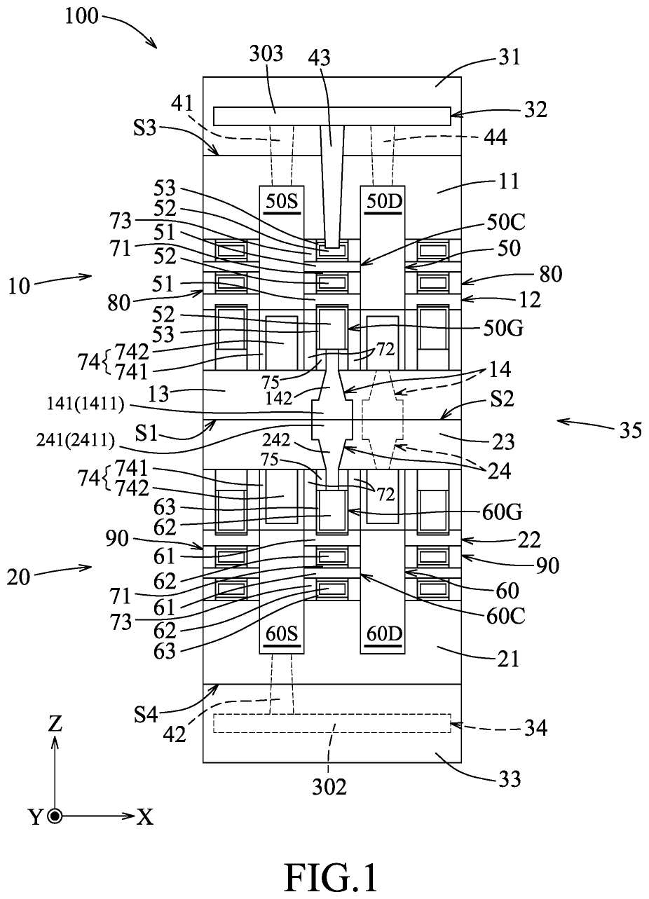

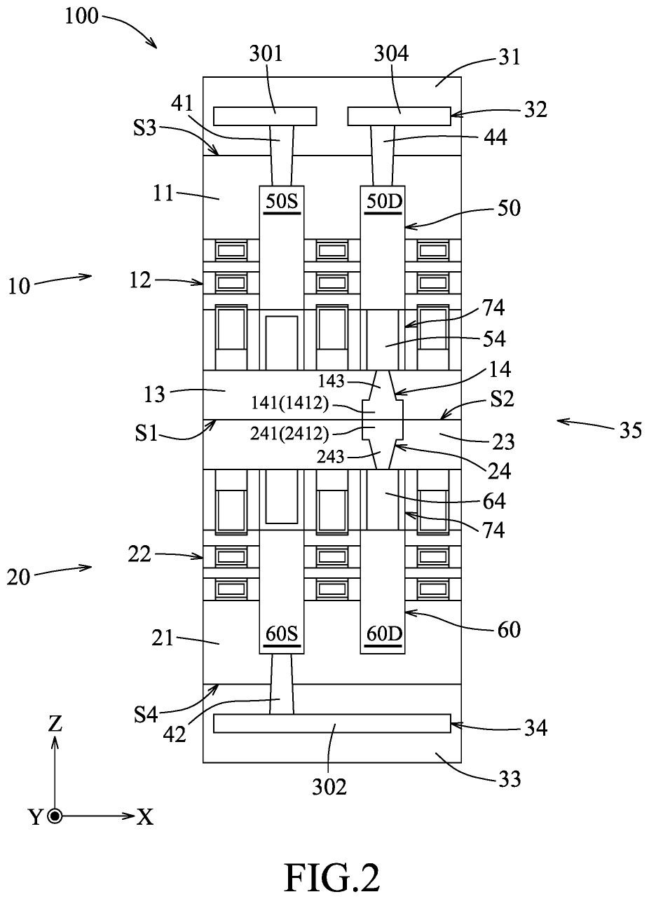

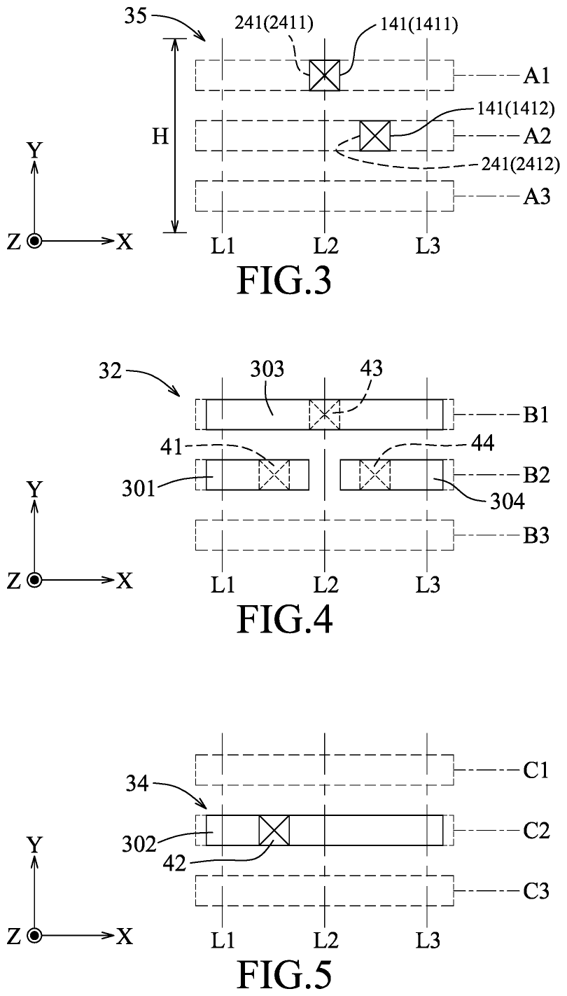

The present disclosure is directed to a semiconductor structure including at least one pair of devices which are stacked on each other and an interconnect structure between the at least one pair of the devices, and a method for manufacturing the semiconductor structure. FIGS. 1 and 2 are schematic sectional views illustrating a semiconductor structure 100 in accordance with some embodiments. FIGS. 3 to 5 are schematic plane views respectively illustrating a middle electrically conductive feature 35, a first electrically conductive feature 32, and a second electrically conductive feature 34 of the semiconductor structure 100 in accordance with some embodiments. It is noted that the middle, first and second electrically conductive features 35, 32, 34 are respectively at different height levels in a Z direction, and some elements are omitted in FIGS. 3 to 5. It is noted that FIG. 1 is a view taken along a first cross section through imaginary areas A1, B1, C1 as shown in FIGS. 3 to 5, respectively, and further illustrates elements omitted in FIGS. 3 to 5; and FIG. 2 is a view taken along a second cross section through imaginary areas A2, B2, C2 as shown in FIGS. 3 to 5, respectively, in which the second cross section is spaced apart from the first cross section in a Y direction transverse to the Z direction, and further illustrates the other elements omitted in FIGS. 3 to 5. Some repeating structures are omitted in FIGS. 1 to 5 for the sake of brevity.

As shown in FIGS. 1 and 2, the semiconductor structure 100 includes a first device assembly 10 and a second device assembly 20. The first device assembly 10 includes a first substrate 11, a first main unit 12, a first dielectric unit 13, and a first electrically conductive routing 14. The second device assembly 20 includes a second substrate 21, a second main unit 22, a second dielectric unit 23, and a second electrically conductive routing 24.

In some embodiments, each of the first and second substrates 11, 21 may be independently made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The material(s) for forming the first and second substrates 11, 21 may be doped with p-type impurities or n-type impurities, or undoped. In addition, each of the first and second substrates 11, 21 may independently be a bulk silicon substrate, a silicon-on-insulator (SOI) substrate, or a germanium-on-insulator (GOI) substrate. Other suitable materials for the first and second substrates 11, 21 are within the contemplated scope of the present disclosure. In some embodiments, each of the first and second substrate 11, 21 may be independently entirely or partially replaced by a dielectric material, such as silicon oxide, silicon nitride, silicon carbide, silicon oxynitride, silicon carbonitride, silicon oxycarbide, silicon oxycarbonitride, other suitable materials, or combinations thereof.

The first main unit 12 is disposed on the first substrate 11, and includes at least one first device 50. The second main unit 22 is disposed on the second substrate 21, and includes at least one second device 60. The number of each of the first and second devices 50, 60 can be varied according to the design of circuit layout of the semiconductor structure 100. In some embodiments, as shown in FIGS. 1 and 2, a single first device 50 and a single second device 60 are exemplified.

In some embodiments, each of the first and second devices 50, 60 may be independently a bipolar junction transistor (BJT), a field-effect transistor (FET), or other suitable devices. In some embodiments, when each of the first and second devices 50, 60 is a FET, each of the first and second devices 50, 60 may be independently configured as a fin-type FET (FinFET), a multi-gate FET (for example, but not limited to, a gate-all-around FET (GAAFET), multi-bridge channel FETs (MBCFET), fork-sheet FETs), or a planar FET, but is not limited thereto. Furthermore, in some embodiments, each of the first and second devices 50, 60 may independently serve as an n-FET or a p-FET according to the design of circuit layout of the semiconductor structure 100. For example, when the first device 50 cooperates with the second device 60 to function as an inverter, one of the first and second devices 50, 60 is an n-FET, and the other one of the first and second devices 50, 60 is a p-FET.

In some embodiments, the first device 50 includes a first channel structure 50C, a first gate structure 50G, a first source feature 50S, and a first drain feature 50D. In some embodiments, as shown in FIGS. 1 and 2, the first device 50 is configured as a GAAFET, and the first channel structure 50C may include a plurality of channel features 51 (two of which are shown in FIGS. 1 and 2) spaced apart from each other in the Z direction. The first gate structure 50G is disposed on the first channel structure 50C, and includes a first gate electrode 52 and a first gate dielectric layer 53 which is disposed between the first gate electrode 52 and the first channel structure 50C. In some embodiments, as shown in FIGS. 1 and 2, the first gate structure 50G wraps around the channel features 51 of the first channel structure 50C. The first source feature 50S and the first drain feature 50D are respectively disposed at two opposite sides of the first gate structure 50G in an X direction transverse to the Y and Z directions such that each of the channel features 51 of the first channel structure 50C extends between the first source feature 50S and the first drain feature 50D.

In some embodiments, the second device 60 includes a second channel structure 60C, a second gate structure 60G, a second source feature 60S, and a second drain feature 60D. In some embodiments, as shown in FIGS. 1 and 2, the second device 60 is configured as a GAAFET, and the second channel structure 60C may include a plurality of channel features 61 (two of which are shown in FIGS. 1 and 2) spaced apart from each other in the Z direction. The second gate structure 60G is disposed on the second channel structure 60C, and includes a second gate electrode 62 and a second gate dielectric layer 63 which is disposed between the second gate electrode 62 and the second channel structure 60C. In some embodiments, as shown in FIGS. 1 and 2, the second gate structure 60G wraps around the channel features 61 of the second channel structure 60C. The second source feature 60S and the second drain feature 60D are respectively disposed at two opposite sides of the second gate structure 60G in the X direction such that each of the channel features 61 of the second channel structure 60C extends between the second source feature 60S and the second drain feature 60D.

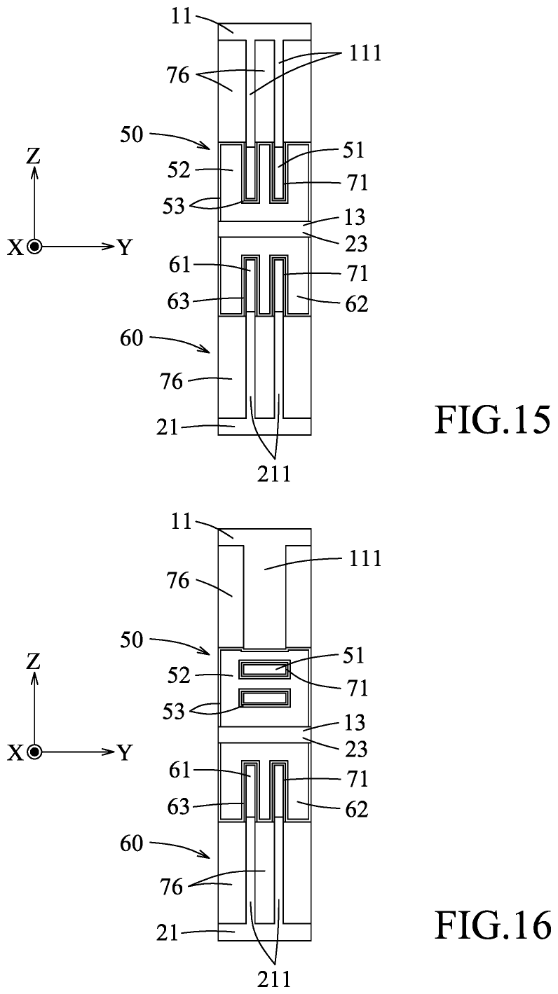

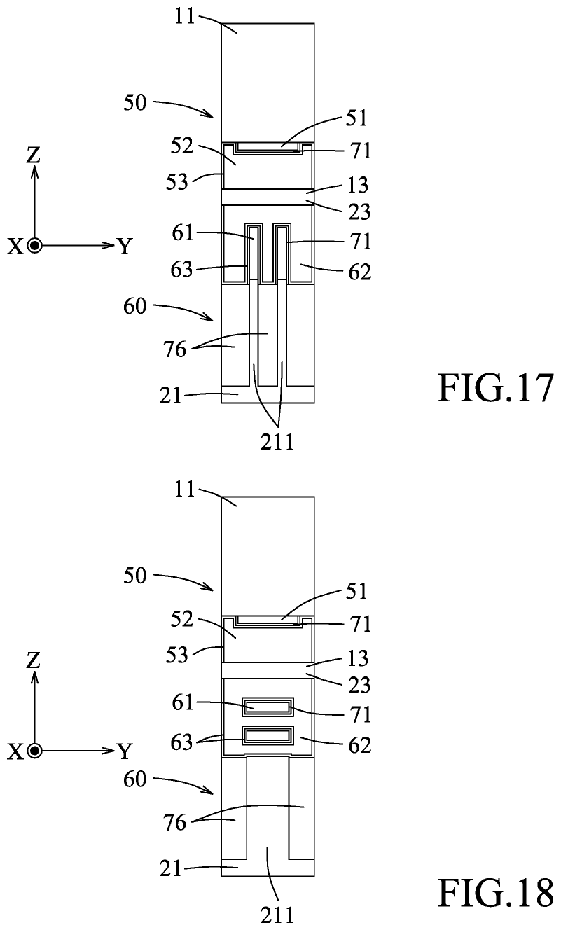

In some embodiments, one of the first and second devices 50, 60 may be configured as a FinFET (see FIG. 16 or 17), while in some other embodiments, each of the first and second devices 50, 60 may be configured as a FinFET (see FIG. 15). Similarly, in some embodiments, one of the first and second devices 50, 60 may be configured as a planar FET (see FIG. 17 or 18), while in some other embodiments, each of the first and second devices 50, 60 may be configured as a planar FET. When the first device 50 is the FinFET or the planar FET, the first channel structure 50C may include a single channel feature 51. When the second device 60 is the FinFET or the planar FET, the second channel structure 60C may include a single channel feature 61.

In some embodiments, as shown in FIGS. 1 and 2, the first and second gate electrodes 52, 62 are spaced apart from and aligned with each other in the Z direction, the first and second drain features 50D, 60D are spaced apart from and aligned with each other in the Z direction, and the first and second source features 50S, 60S are spaced apart from and aligned with each other in the Z direction.

In some embodiments, possible materials for forming the channel features 51, 61 may be similar to those for forming the first and second substrates 11, 21. In some other embodiments, the channel feature 51 of the planar FET shown in FIG. 17 or 18 includes a two dimensional (2D) material such as a transition metal dichalcogenide including molybdenum disulfide (MoS₂), tungsten disulfide (WS₂), and tungsten diselenide (WSe₂), or other suitable materials. In some embodiments, the channel features 51 of the first channel structure 50C may be made from a material the same as or different from that of the channel features 61 of the second channel structure 60C according to application requirements. For example, in some embodiments, the channel features 51, 61 of the first and second channel structure 50C, 60C may be made of silicon, while in some other embodiments, the channel features 51 of the first channel structure 50C is made of silicon, and the channel features 61 of the second channel structure 60C is made of silicon germanium, or vice versa. In some embodiments, the channel features 51 of the first channel structure 50C may be made from a material the same as or different from that of the first substrate 11 according to application requirements. In some embodiments, the channel features 61 of the second channel structure 60C may be made from a material the same as or different from that of the second substrate 21 according to application requirements.

In some embodiments, the first substrate 11 has a first inner surface for the first main unit 12 to be disposed thereon, and the second substrate 21 has a second inner surface for the second main unit 22 to be disposed thereon. The first and second inner surfaces may independently have a {100} crystal plane, a {110} crystal plane, or a crystal plane with other suitable crystal orientation according to application requirements. Each of the channel features 51 of the first channel structure 50C has lateral surfaces respectively in contact with the first source feature 50S and the first drain feature 50D. In some embodiments, the lateral surfaces of the channel features 51 of the first channel structure 50C may have a {100} crystal plane, a {110} crystal plane, or a crystal plane with other suitable crystal orientation according to application requirements. Each of the channel features 61 of the second channel structure 60C has lateral surfaces respectively in contact with the second source feature 60S and the second drain feature 60D. In some embodiments, the lateral surfaces of the channel features 61 of the second channel structure 60C may have a {100} crystal plane, a {110} crystal plane, or a crystal plane with other suitable crystal orientation according to application requirements.

In some embodiments, each of the first and second gate electrodes 52, 62 may be configured as a multi-layered structure including at least one work function metal which is provided for adjusting threshold voltage of an n-FET or a p-FET, an electrically conductive material having a low resistance which is provided for reducing electrical conductivity of the first and second gate electrodes 52, 62, other suitable materials, or combinations thereof. In some embodiments, the work function metal for forming an n-FET may be different from that for forming a p-FET, so as to permit the n-FET and the p-FET to have different threshold voltages. Other suitable methods for adjusting the threshold voltages are within the contemplated scope of the present disclosure. In some embodiments, each of the first and second gate electrodes 52, 62 independently includes a metal material (e.g., tungsten (W), titanium (Ti), tantalum (Ta), aluminum (Al), or ruthenium (Ru)), metal-containing nitrides (e.g., titanium nitride (TiN), or tantalum nitride (TaN)), metal-containing silicides (e.g., nickel silicide (NiSi)), metal-containing carbides (e.g., tantalum carbide (TaC)), or combinations thereof. Other suitable materials for the first and second gate electrodes 52, 62 are within the contemplated scope of the present disclosure. In some embodiments, each of the first and second gate dielectric layers 53, 63 independently includes silicon oxide, silicon nitride, silicon oxynitride, a high dielectric constant (high-k) material (such as hafnium oxide, zirconium oxide, zirconium aluminum oxide, hafnium aluminum oxide, hafnium silicon oxide, aluminum oxide, and so on), other suitable materials, or combinations thereof. Other suitable materials for the first and second gate dielectric layers 53, 63 are within the contemplated scope of the present disclosure.

In some embodiments, each of the first source feature 50S, the first drain feature 50D, the second source feature 60S, and the second drain feature 60D may be doped with an n-type impurity or a p-type impurity, and may be formed as a single layer structure or a multi-layered structure having several sub-layers with different doping concentration. For example, in some embodiments, the second source feature 60S and the second drain feature 60D may have an n-type conductivity, and includes single crystalline silicon, polycrystalline silicon or other suitable materials doped with an n-type impurity, so as to function as a source/drain of an n-FET. The n-type impurity may be, for example, but not limited to, nitrogen (N), phosphorous (P), arsenic (As), antimony (Sb), other suitable materials, or combinations thereof. In some embodiments, the first source feature 50S and the first drain feature 50D may have a p-type conductivity, and includes single crystalline or polycrystalline silicon, single crystalline or polycrystalline silicon germanium, or other suitable materials doped with a p-type impurity, so as to function as a source/drain of a p-FET. The p-type impurity may be, for example, but not limited to, boron (B), aluminum (Al), gallium (Ga), indium (In), other suitable materials, or combinations thereof. In some embodiments, each of the first source feature 50S and the second source feature 60S can serve as a source, and each of the first drain feature 50D and the second drain feature 60D can serve as a drain; while in some other embodiments, each of the first source feature 50S and the second source feature 60S can serve as a drain, and each of the first drain feature 50D and the second drain feature 60D can serve as a source.

In some embodiments, each of the first and second devices 50, 60 further includes a plurality of interfacial layers 71, two gate spacers 72, a plurality of inner spacers 73, two isolation features 74 each of which includes a contact etching stop portion 741 and an inter-layer dielectric (ILD) portion 742, and a cap layer 75. In some embodiments, each of the interfacial layers 71, the gate spacers 72, the inner spacers 73, the isolation features 74, and the cap layer 75 is independently made of a dielectric material, such as silicon oxide, silicon nitride, silicon carbide, silicon oxynitride, silicon carbonitride, silicon oxycarbide, silicon oxycarbonitride, or combinations thereof. Other suitable materials for each of the interfacial layers 71, the gate spacers 72, the inner spacers 73, the isolation features 74, and the cap layer 75 are within the contemplated scope of the present disclosure.

In some embodiments, each of the interfacial layers 71 in the first device 50 is disposed between the first gate dielectric layer 53 and a corresponding one of the first channel features 51 for improving film quality of the first dielectric layer 53 which is formed to wrap the first channel features 51. In some embodiments, the two gate spacers 72 in the first device 50 are respectively disposed at two sides of the first gate structure 50G, and are opposite to each other in the X direction. In some embodiments, the two gate spacers 72 are disposed on the first channel structure 50C opposite to the first substrate 11. In some embodiments, each of the inner spacers 73 in the first device 50 is disposed between the first gate structure 50G and a corresponding one of the first source feature 50S and the first drain feature 50D for electrical isolation therebetween. In some embodiments, the two isolation features 74 in the first device 50 are respectively disposed on the first source feature 50S and the first drain feature 50D. In some embodiments, in the first device 50, the cap layer 75 is disposed on the first gate structure 50G opposite to the first substrate 11, and has an outer surface which is opposite to the first substrate 11, and which is flush with that of the isolation feature 74.

In some embodiments, each of the interfacial layers 71 in the second device 60 is disposed between the second gate dielectric layer 63 and a corresponding one of the second channel features 61 for improving film quality of the second dielectric layer 63 which is formed to wrap the second channel features 61. In some embodiments, the two gate spacers 72 in the second device 60 are respectively disposed at two sides of the second gate structure 60G, and are opposite to each other in the X direction. In some embodiments, the two gate spacers 72 are disposed on the second channel structure 60C opposite to the second substrate 21. In some embodiments, each of the inner spacers 73 in the second device 60 is disposed between the second gate structure 60G and a corresponding one of the second source feature 60S and the second drain feature 60D for electrical isolation therebetween. In some embodiments, the two isolation features 74 in the second device 60 are respectively disposed on the second source feature 60S and the second drain feature 60D. In some embodiments, in the second device 60, the cap layer 75 is disposed on the second gate structure 60G opposite to the second substrate 21, and has an outer surface which is opposite to the second substrate 21, and which is flush with that of the isolation feature 74.

In some embodiments, the first main unit 12 further includes a pair of first dummy portions 80 which are respectively disposed at two sides of the first device 50, and which are opposite to each other in the X direction. The first dummy portions 80 are simultaneously formed with formation of the first device 50, and hence, in some embodiments, each of the first dummy portions 80 has a structure similar to that of the first device 50 but without the first source feature 50S, the first drain feature 50D, and the isolation features 74. In some embodiments, the second main unit 22 further includes two second dummy portions 90 which are respectively disposed at two sides of the second device 60, and which are opposite to each other in the X direction. The second dummy portions 90 are simultaneously formed with formation of the second device 60, and hence, in some embodiments, each of the second dummy portions 90 has a structure similar to that of the second device 60 but without the second source feature 60S, the second drain feature 60D, and the isolation features 74. In some embodiments, each of the first and second dummy portions 80, 90 may be independently replaced by a dielectric material, such as silicon oxide, silicon nitride, silicon carbide, silicon oxynitride, silicon carbonitride, silicon oxycarbide, silicon oxycarbonitride, or combinations thereof.

As shown in FIGS. 1 and 2, the first dielectric unit 13 is disposed on the first main unit 12 opposite to the first substrate 11, and has a first interconnecting surface S1 opposite to the first substrate 11. The first electrically conductive routing 14 is disposed in the first dielectric unit 13, and is electrically connected to the first device 50. The first electrically conductive routing 14 has a first end portion 141 opposite to the first substrate 11. The second dielectric unit 23 is disposed on the second main unit 22 opposite to the second substrate 21, and has a second interconnecting surface S2 which is opposite to the second substrate 21. The second electrically conductive routing 24 is disposed in the second dielectric unit 23, and is electrically connected to the second device 60. The second electrically conductive routing 24 has a second end portion 241 opposite to the second substrate 21. The first interconnecting surface S1 is bonded to the second interconnecting surface S2 such that the second end portion 241 of the second electrically conductive routing 24 is in direct contact with the first end portion 141 of the first electrically conductive routing 14.

In some embodiments, each of the first and second dielectric units 13, 23 may include a low dielectric constant (low-k) material (such as silicon oxide, silicon nitride, silicon oxynitride, silicon carbonitride, silicon oxycarbide, silicon oxycarbonitride, silicon carbide, and so on), but is not limited thereto. In some embodiments, each of the first and second electrically conductive routings 14, 24 may be made of an electrically conductive material which includes, for example, but not limited to, copper, tungsten, cobalt, ruthenium, aluminum, palladium, nickel, platinum, a low resistivity metal constituent, or the like, or combinations thereof. Other suitable materials for the first and second electrically conductive routings 14, 24 are within the contemplated scope of the present disclosure. The first and second electrically conductive routings 14, 24 are together referred to as the middle electrically conductive feature 35.

Referring to FIG. 3, a plurality of imaginary areas A1, A2, A3 represent regions where vias and/or tracks (i.e., the first end portion 141 of the first electrically conductive routing 14 and the second end portion 241 of the second electrically conductive routing 24) may be designed, and the configuration (e.g., shape, dimension, or number) of the regions A1, A2, A3 may vary according to the design of circuit layout of the semiconductor structure 100. In some embodiments, as shown in FIG. 3, the regions A1, A2, A3 are arranged to be elongated in the X direction and spaced apart from each other in the Y direction, but is not limited thereto. In some embodiments, the X, Y and Z directions are perpendicular to one another. In some embodiments, the semiconductor structure 100 has a cell height (H) in the Y direction. The number of the regions A1, A2, A3 which are able to be arranged in a single cell height (H) may range from about two to three. In some embodiments, as shown in FIG. 3, the number of the regions A1, A2, A3 arranged in a single cell height (H) is three, but is not limited thereto. In addition, three of the reference lines L1, L2, L3 are shown in FIG. 3, and are also shown in each of FIGS. 4 and 5. The reference line L2 represents a position where the first and second gate structures 50G, 60G are aligned with each other in the Z direction, and the first and second gate structures 50G, 60G are respectively located at a level higher and lower than that of the middle electrically conductive feature 35 in the Z direction. The reference line L1 represents a position where a left one of the first dummy portions 80 and a left one of the second dummy portions 90 (see FIG. 1) are aligned with each other in the Z direction. The reference line L3 represents a position where a right one of the first dummy portions 80 and a right one of the second dummy portions 90 (see FIG. 1) are aligned with each other in the Z direction. It is noted that the reference line L2 does not indicate a length of the first and second gate structures 50G, 60G. Each of the first and second gate structures 50G, 60G may have a length in the Y direction which may be equal to or smaller than that of the reference line L2 according to processes to be performed subsequently. In some embodiments, as shown in FIGS. 1 and 3, the first end portion 141 of the first electrically conductive routing 14 is entirely overlapped with the second end portion 241 of the second electrically conductive routing 24. The middle electrically conductive feature 35 may be entirely or partially disposed between the first and second devices 50, 60 (see FIGS. 1 and 2), and has a function for communicating the first and second devices 50, 60. When the middle electrically conductive feature 35 is entirely disposed between the first and second devices 50, 60, the semiconductor structure 100 may occupy a relatively smaller chip area, thereby increasing an integration density of a circuit.

In some embodiments, as shown in FIGS. 1 to 3, the first end portion 141 of the first electrically conductive routing 14 includes a first gate pad 1411 (see FIGS. 1 and 3) and a first drain pad 1412 (see FIGS. 2 and 3), and the second end portion 241 of the second electrically conductive routing 24 includes a second gate pad 2411 (see FIGS. 1 and 3) and a second drain pad 2412 (see FIGS. 2 and 3).

In some embodiments, as shown in FIG. 1, the first electrically conductive routing 14 further includes a first gate via 142 which extends in the Z direction toward the second gate electrode 62 to terminate at the first gate pad 1411, so as to permit the first gate electrode 52 to be electrically connected the first gate pad 1411 through the first gate via 142. In some embodiments, the first gate via 142 further extends through the cap layer 75 of the first device 50 to be in electrically contact with the first gate electrode 52. In some embodiments, the first gate via 142 and the first gate pad 1411 may be simultaneously formed, and together formed into a gate via feature. In some embodiments, the first gate pad 1411 may have a dimension in the X and/or Y directions greater than that of the first gate via 142. The second electrically conductive routing 24 further includes a second gate via 242 which extends in the Z direction toward the first gate electrode 52 to terminate at the second gate pad 2411, so as to permit the second gate electrode 62 to be electrically connected to the second gate pad 2411 through the second gate via 242. In some embodiments, the second gate via 242 further extends through the cap layer 75 of the second device 60 to be in electrically contact with the second gate electrode 62. In some embodiments, the second gate via 242 and the second gate pad 2411 may be simultaneously formed, and together formed into another gate via feature. In some embodiments, the second gate pad 2411 may have a dimension in the X and/or Y directions greater than that of the second gate via 242. The first and second gate pads 1411, 2411 are in direct contact with each other, so as to permit the first gate electrode 52 to be electrically connected to the second gate electrode 62 through the first and second gate vias 142, 242 and the first and second gate pads 1411, 2411. It is noted that the first gate pad 1411 is entirely overlapped with the second gate pad 2411, as shown in FIGS. 1 and 3. The first and second gate pads 1411, 2411, and the first and second gate vias 142, 242 are disposed together in position between the first and second gate electrodes 52, 62.

In some embodiments, as shown in FIG. 2, the first electrically conductive routing 14 further includes a first drain via 143 which extends in the Z direction toward the second drain feature 60D to terminate at the first drain pad 1412, so as to permit the first drain feature 50D to be electrically connected to the first drain pad 1412 through the first drain via 143. In some embodiments, the first device 50 further includes a first contact feature 54 which is formed in a corresponding one of the isolation features 74 such that the first contact feature 54 is disposed between the first drain feature 50D and the first drain via 143 for electrical connection therebetween. In some embodiments, the first drain via 143 and the first drain pad 1412 may be simultaneously formed, and together formed into a drain via feature. In some embodiments, the first drain pad 1412 may have a dimension in the X and/or Y directions greater than that of the first drain via 143. The second electrically conductive routing 24 further includes a second drain via 243 which extends in the Z direction toward the first drain feature 50D to terminate at the second drain pad 2412, so as to permit the second drain feature 60D to be electrically connected to the second drain pad 2412 through the second drain via 243. In some embodiments, the second device 60 further includes a second contact feature 64 which is formed in a corresponding one of the isolation features 74 such that the second contact feature 64 is disposed between the second drain feature 60D and the second drain via 243 for electrical connection therebetween. In some embodiments, the second drain via 143 and the second drain pad 1412 may be simultaneously formed, and together formed into another drain via feature. In some embodiments, the second drain pad 2412 may have a dimension in the X and/or Y directions greater than that of the second drain via 243. In some embodiments, possible electrically conductive materials suitable for forming each of the first and second contact features 54, 64 are similar to those for forming the first and second electrically conductive routings 14, 24, and thus details thereof are omitted for the sake of brevity.

The first and second drain pads 1412, 2412 are in direct contact with each other, so as to permit the first drain feature 50D to be electrically connected to the second drain feature 60D through the first and second drain vias 143, 243, the first and second drain pads 1412, 2412, and the first and second metal contacts 54, 64. It is noted that the first drain pad 1412 is entirely overlapped with the second drain pad 2412, as shown in FIGS. 2 and 3. The first and second gate pads 1411, 2411, and the first and second gate vias 142, 242 are disposed together in position between the first and second gate electrodes 52, 62. In some not shown embodiments, the first source feature 50S may be electrically connected to the second source feature 60S in a manner similar to that of the electrical connection between the first drain feature 50D and the second drain feature 60D, according to the design of circuit layout of the semiconductor structure 100.

In some embodiments, according to a position and a dimension of each of the first and second gate electrodes 52, 62 (for example, a length of each of the first and second gate electrodes 52, 62 in the Y direction) and according to a position and a dimension of each of the first and second contact features 54, 64 (for example, a length of each of the first and second contact features 54, 64 in the Y direction), the first gate pad 1411 (or the second gate pad 2411) and the first drain pad 1412 (or the second drain pad 2412) are staggered from each other in the X direction, so as to ensure that a distance between the first gate pad 1411 (or the second gate pad 2411) and the first drain pad 1412 (or the second drain pad 2412) is sufficient for electrical isolation. For example, as shown in FIG. 3, the first and second gate pads 1411, 2411 are positioned at the region A1 and on the reference line L2, and the first and second drain pads 1412, 2412 are positioned at the region A2 and between the reference lines L2, L3. In some not shown embodiments, (i) each of the first and second gate pads 1411, 2411 may be positioned on the reference line L2, (ii) each of the first and second drain pads 1412, 2412 may be positioned between the reference lines L2, L3, and (iii) the first gate pad 1411 (or the second gate pad 2411) and the first drain pad 1412 (or the second drain pad 2412) are staggered from each other in the X direction to be located on the same or different ones of the regions A1, A2, A3. When the first and second gate pads 1411, 2411 are positioned at one of the regions A1, A2, A3 different from that of the first and second drain pads 1412, 2412 (for example, as shown in FIG. 3), the first gate pad 1411 (or the second gate pad 2411) and the first drain pad 1412 (or the second drain pad 2412) are staggered from each other in both the X and Y directions. As such, a distance between the first gate pad 1411 (or the second gate pad 2411) and the first drain pad 1412 (or the second drain pad 2412) may be relatively large, thereby reducing occurrence of bridging defect therebetween.

As shown in FIGS. 1 and 2, the first substrate 11 has a first outer surface S3 opposite to the second device assembly 20, and the second substrate 21 has a second outer surface S4 opposite to the first device assembly 10.

In some embodiments, as shown in FIGS. 1 and 2, the semiconductor structure 100 further includes a first dielectric feature 31 and a second dielectric feature 33. The first dielectric feature 31 is disposed on the first outer surface S3 of the first substrate 11, and the first electrically conductive feature 32 is formed in the first dielectric feature 31. The second dielectric feature 33 is disposed on the second outer surface S4 of the second substrate 21, and the second electrically conductive feature 34 is formed in the second dielectric feature 33. As such, the first and second devices 50, 60 are permitted to be electrically connected to external circuits through the first and second electrically conductive features 32, 34. In some embodiments, possible dielectric materials suitable for forming the first and second dielectric features 31, 33 are similar to those for forming the first and second dielectric units 13, 23, possible electrically conductive materials suitable for forming the first and second electrically conductive features 32, 34 are similar to those for forming the first and second electrically conductive routings 14, 24, and thus details thereof are omitted for the sake of brevity.

Each of the first and second electrically conductive features 32, 34 includes at least one track. In some embodiments, as shown in FIGS. 1 and 2, the first electrically conductive feature 32 includes a first track 301, a second track 303 and a third track 304, and the second electrically conductive feature 34 includes a fourth track 302.

In some embodiments, the semiconductor structure 100 further includes a first power via 41, a second power via 42, an input via 43, and an output via 44. As shown in FIG. 2, the first power via 41 extends from the first track 301 of the first electrically conductive feature 32 into the first substrate 11 to reach the first source feature 50S of the first device 50, so as to permit a first voltage to be applied to the first source feature 50S of the first device 50 through the first power via 41. The second power via 42 extends from the second track 302 of the second electrically conductive feature 34 into the second substrate 21 to reach the second source feature 60S of the second device 60, so as to permit a second voltage to be applied to the second source feature 60S of the second device 60 through the second power via 42. Each of the first and second voltages may independently have a value according to the operation of the semiconductor structure 100.

In some embodiments, as shown in FIG. 1, the input via 43 extends from the third track 303 of the first electrically conductive feature 32 into the first substrate 11 to reach the first gate electrode 52 of the first device 50, so as to permit an input signal from the input via 43 to be transmitted to the first device 50. Since the first gate electrode 52 is electrically connected to the second gate electrode 62 as described above, the input signal is transmitted to the second device 60 as well. In some other embodiments, an alternative input via (not shown) may extend from another track (not shown) of the second electrically conductive feature 34 into the second substrate 21 from the second outer surface S4 to reach the second gate electrode 62 of the second device 60, so as to permit the input signal from the alternative input via to be transmitted to the first and second devices 50, 60. In some embodiments, as shown in FIG. 2, the output via 44 extends from the fourth track 304 into the first substrate 11 to reach the first drain feature 50D of the first device 50, so as to permit an output signal in response to the input signal to be output through the output via 44. Since the first drain feature 50D is electrically connected to the second drain feature 60D as described above, the output signal is generated by signal processing of the first and second devices 50, 60. In some other embodiments, an alternative output via (not shown) may extend from a yet another track (not shown) of the second electrically conductive feature 34 into the second substrate 21 from the second outer surface S4 to reach the second drain feature 60D of the second device 60, so as to permit the output signal in response to the input signal to be output through the alternative output via. In some embodiments, possible electrically conductive materials suitable for forming each of the first and second power vias 41, 42, and the input and output vias 43, 44 are similar to those for forming the first and second electrically conductive routings 14, 24, and thus details thereof are omitted for the sake of brevity.

In addition to the first electrically conductive feature 32, FIG. 4 further schematically illustrates positions of the first power via 41, the input via 43, and the output via 44 in accordance with some embodiments. As shown in FIG. 4, a plurality of imaginary regions B1, B2, B3 are shown to represent regions where vias and tracks (for example, but not limited to, the first electrically conductive feature 32) may be designed. In some embodiments, as shown in FIG. 4, the regions B1, B2, B3 are arranged in a manner similar to that of the regions A1, A2, A3 as described above with reference to FIG. 3, and thus details thereof are omitted for the sake of brevity. In addition to the second electrically conductive feature 34, FIG. 5 further schematically illustrates a position of the second power via 42 in accordance with some embodiments. As shown in FIG. 5, a plurality of imaginary regions C1, C2, C3 are shown to represent regions where vias and tracks (for example, but not limited to, the second electrically conductive feature 34) may be designed. It is noted that the configuration (e.g., shape, dimension, or number) of the regions B1, B2, B3, C1, C2, C3 may vary according to the design of circuit layout of the semiconductor structure 100. In some embodiments, as shown in FIG. 5, the regions C1, C2, C3 are arranged in a manner similar to that of the regions A1, A2, A3 as described above with reference to FIG. 3, and thus details thereof are omitted for the sake of brevity.

In some embodiments, according to a position and a dimension of each of the first and second gate electrodes 52, 62 (for example, a length of each of the first and second gate electrodes 52, 62 in the Y direction) and according to a position and a dimension of each of the first source feature 50S and the first drain feature 50D (for example, a length of each of the first source feature 50S and the first drain feature 50D in the Y direction), the tracks 301, 303, 304 are arranged in any possible manner to permit the vias 41, 43, 44 respectively extending from the tracks 301, 303, 304 to be electrically isolated from each other in the first dielectric feature 31 and to be respectively and electrically connected to the first source feature 50S, the first gate electrode 52 and the first drain feature 50D (see also FIGS. 1 and 2). For example, as shown in FIG. 4, the third track 303 is located at the region B1, and is electrically connected to the input via 43 at the reference line L2. The first and fourth tracks 301, 304 are located at the region B2, and are spaced apart from each other in the X direction. The first track 301 is electrically connected to the first power via 41 between the reference lines L1, L2, and the fourth track 304 is electrically connected to the output via 44 between the reference lines L2, L3. In some embodiments, according to a position and a dimension of the second source feature 60S (for example, a length of the second source feature 60S in the Y direction), the track 302 is arranged in any possible manner to permit the second power via 42 extending from the track 302 to be electrically connected to the second source feature 60S (see also FIGS. 1 and 2). For example, as shown in FIG. 5, the second track 302 is located at the region C2, and is electrically connected to the second power via 42 between the reference lines L1, L2.

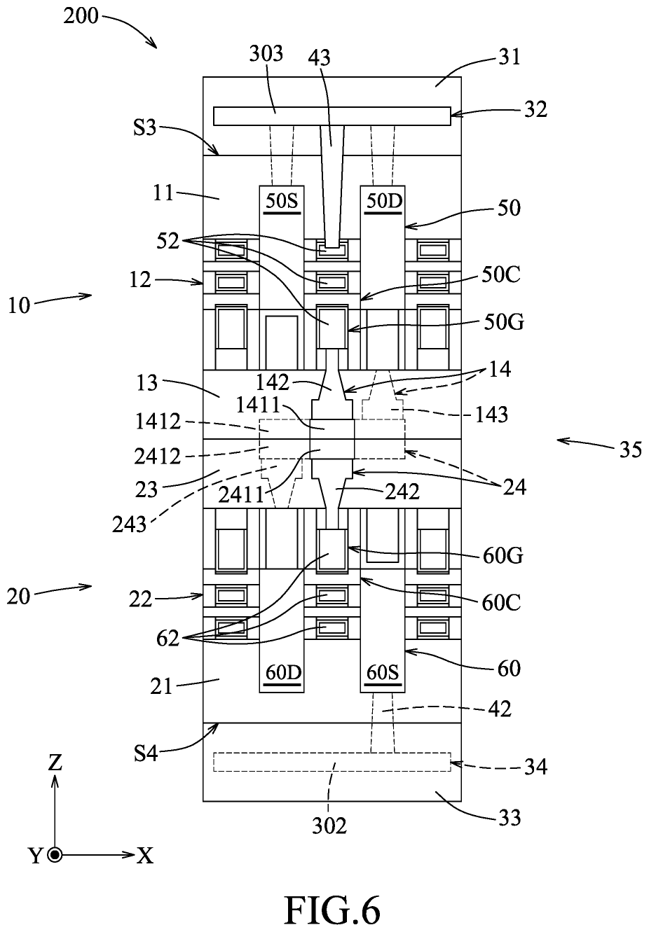

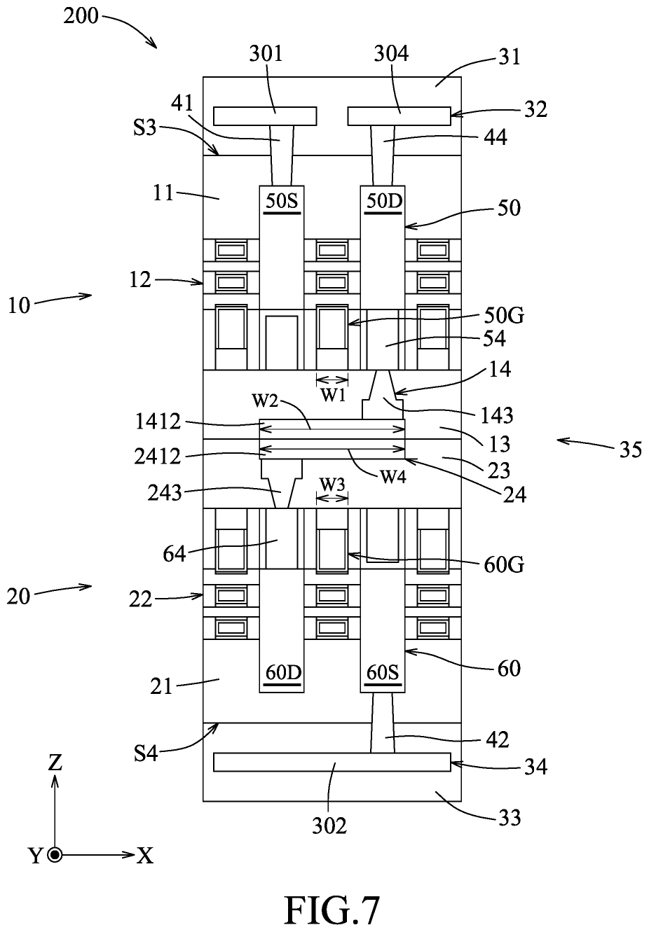

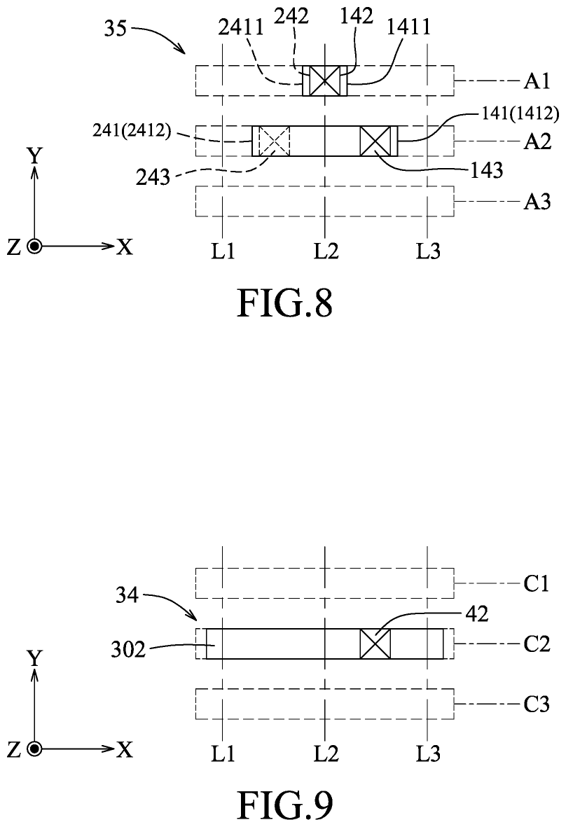

FIGS. 6 and 7 are views respectively similar to those of FIGS. 1 and 2, but illustrating schematic sectional views of a semiconductor structure 200 in accordance with some embodiments. FIG. 8 is a view similar to that of FIG. 3, but schematically illustrates the middle electrically conductive feature 35 of the semiconductor structure 200 in accordance with some embodiments. FIG. 9 is a view similar to that of FIG. 5, but schematically illustrates the second electrically conductive feature 34 and the second power via 42 of the semiconductor structure 200. In some embodiments, a schematic plane view illustrating the first electrically conductive feature 32, the first power via 41, the input via 43, and the output via 44 of the semiconductor structure 200 may be substantially the same as the view shown in FIG. 4, and thus FIG. 4 may be referred to. Some repeating structures are omitted in FIGS. 6 to 9 for the sake of brevity. It is noted that similar numerals from the above-mentioned embodiments are used where appropriate, with some construction differences being indicated with different numerals.

The semiconductor structure 200 has a structure similar to that of the semiconductor structure 100, but has the differences as described in the following.

As shown in FIG. 7, the first drain feature 50D and the second source feature 60S are spaced apart from and aligned with each other in the Z direction, and the first source feature 50S and the second drain feature 60D are spaced apart from and aligned with each other in the Z direction. Accordingly, the first drain via 143 extends in the Z direction toward the second source feature 60S to terminate at the first drain pad 1412, so as to permit the first drain feature 60D to be electrically connected to the first drain pad 1412 through the first drain via 143, and the second drain via 243 extends in the Z direction toward the first source feature 50S to terminate at the second drain pad 2412, so as to permit the second drain feature 60D to be electrically connected to the second drain pad 2412 through the second drain via 243. In this case, since the first drain via 143 and the second drain via 243 are located at two opposite sides of the first gate structure 50G (or the second gate structure 60G) in the X direction, the first and second drain pads 1412, 2412 are in direct contact with each other, and are together formed into a track elongated in the X direction, so as to electrically connect the first and second drain vias 143, 243. The first and second drain pads 1412, 2412 extends across the first and second gate structures 50G, 60G. In some embodiments, each of the first and second drain vias 143, 243 has a dimension in the X direction which is much less than that of a corresponding one of the first and second drain pads 1412, 2412.

In some embodiments, the first gate structure 50G has a first gate width W1 in the X direction, and the second gate structure 60G has a second gate width W3 in the X direction. The first drain pad 1412 has a pad width W2 in the second direction, and the second drain pad 2412 has a pad width W4 in the X direction. The pad width W2 is substantially equal to the pad width W4, and each of the pad widths W2, W4 is not less than each of the first and second gate widths W1, W3. In some embodiments, each of the pad widths W2, W4 is greater than each of the first and second gate widths W1, W3.

Furthermore, in some embodiments, as shown in FIG. 7, in order to accommodate the first and second drain pads 1412, 2412 and the first and second drain vias 143, 243, the first and second dielectric units 13, 23 of the semiconductor structure 200 have a total thickness in the Z direction which is greater than that of the first and second dielectric units 13, 23 in the semiconductor structure 100 shown in FIG. 2.

As shown in FIG. 6, the first gate pad 1411 and the first gate via 142 have a total length in the Z direction which is greater than that of the first gate pad 1411 and the first gate via 142 in the semiconductor structure 100 shown in FIG. 1 due to the thicker first dielectric unit 13 in the semiconductor structure 200. In some embodiments, the first gate pad 1411 is located at a height level equal to that of the first drain pad 1412, and the first gate via 142 is located at a height level equal to that of the first drain via 143. In some embodiments, as shown in FIG. 6, the first gate via 142 has a dimension in the X and/or Y direction less than that of the first gate pad 1411.

The second gate pad 2411 and the second gate via 242 have a total length in the Z direction which is greater than that of the second gate pad 2411 and the second gate via 242 in the semiconductor structure 100 shown in FIG. 1 due to the thicker second dielectric unit 23 in the semiconductor structure 200. In some embodiments, the second gate pad 2411 is located at a height level equal to that of the second drain pad 2412, and the second gate via 242 is located at a height level equal to that of the second drain via 243. In some embodiments, as shown in FIG. 6, the second gate via 242 has a dimension in the X and/or Y direction less than that of the second gate pad 2411.

In some embodiments, according to a position or a dimension of each of the first and second gate electrodes 52, 62 (for example, a length of each of the first and second gate electrodes 52, 62 in the Y direction) and according to a position and a dimension of each of the first and second contact features 54, 64 (for example, a length of each of the first and second contact features 54, 64 in the Y direction), the first gate pad 1411 (or the second gate pad 2411) and the first drain pad 1412 (or the second drain pad 2412) are staggered from each other in the Y direction, so as to ensure that a distance between the first gate pad 1411 (or the second gate pad 2411) and the first drain pad 1412 (or the second drain pad 2412) is sufficient for electrical isolation. For example, as shown in FIG. 8, the first drain pad 1412 is spaced apart from the first gate pad 1411 in the Y direction, and the second drain pad 2412 is spaced apart from the second gate pad 2411 in the Y direction. In some embodiments, the first and second drain pads 1412, 2412 are positioned at the region A2 and extend cross the reference line L2 in the X direction. In some not shown embodiments, (i) each of the first and second gate pads 1411, 2411 may be positioned on the reference line L2, (ii) each of the first and second drain pads 1412, 2412 may be positioned between the reference lines L1, L3 to extend across the reference line L2, and (iii) the first gate pad 1411 (or the second gate pad 2411) and the first drain pad 1412 (or the second drain pad 2412) are staggered from each other in the Y direction to be located on different ones of the regions A1, A2, A3. In the semiconductor structure 200, the designs of the tracks 301, 302, 303, 304 and the vias 41, 42, 43, 44 respectively extending from the tracks 301, 302, 303, 304 may be arranged in any possible manner as described above with reference to FIGS. 4 and 5, and the details thereof are omitted for the sake of brevity. In some embodiments, as shown in FIG. 9, the second track 302 is located at the region C2, and is electrically connected to the second power via 42 between the reference lines L2, L3.

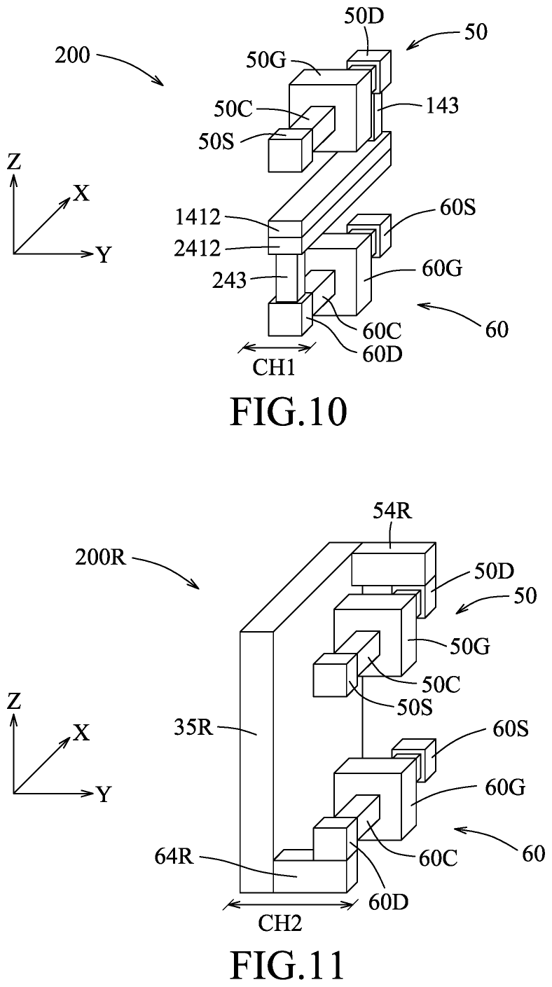

FIG. 10 is a schematic view illustrating an electrical connection between the first and second devices 50, 60 of the semiconductor structure 200 in accordance with some embodiments. FIG. 11 is a schematic view illustrating another electrical connection between the first and second devices 50, 60 of a reference semiconductor structure 200R in accordance with some embodiments. In each of the semiconductor structures 200, 200R, the first and second drain features 50D, 60D are located at two opposite sides of the first gate structure 50G (or the second gate structure 60G) in the X direction.

The semiconductor structure 200 shown in FIG. 10 has a structure similar to that of the semiconductor structure 200 shown in FIG. 7, but FIG. 10 schematically illustrates, without being drawn to scale, the relative positions among the first and second channel structures 50C, 60C, the first and second gate structures 50G, 60G, the first and second source features 50S, 60S, the first and second drain features 50D, 60D, the first and second drain vias 143, 243, and the first and second drain pads 1412, 2412 without structural details, and other elements are omitted. As shown in FIG. 10, the first and second drain features 50D, 60D are interconnected to each other through the first and second drain vias 143, 243 which are elongated in the Z direction, and the first and second drain pads 1412, 2412 which are elongated in the X direction. The first and second drain vias 143, 243 and the first and second drain pads 1412, 2412 are all interposed between the first and second devices 50, 60 without increasing an occupied chip area.

The reference semiconductor structure 200R shown in FIG. 11 has a structure similar to that of the semiconductor structure 200 shown in FIG. 10, except for the following differences. As shown in FIG. 11, the first and second drain vias 143, 243 and the first and second drain pads 1412, 2412 shown in FIG. 10 are absent, and the reference semiconductor structure 200R further includes a first contact portion 54R, a second contact feature 64R and a vertical interconnecting portion 35R, so as to permit the first and second drain features 50D, 60D to be electrically connected to each other. The first contact portion 54R is disposed on the first drain feature 50D opposite to the second device 60, and is elongated in the Y direction to a lateral area (for example, an area at a left side of the first device 50). The second contact portion 64R is disposed on the second drain feature 50D opposite to the first device 50, and is elongated in the Y direction to a lateral area (for example, an area at a left side of the second device 60). The vertical interconnecting portion 35R is elongated in the X and Y directions to interconnect the first and second contact portions 54R, 64R without affecting the first and second devices 50, 60.

In some embodiments, as shown in FIGS. 10 and 11, when the first and second devices 50, 60 of the semiconductor structure 200 has the same dimension and configuration as those of the first and second devices 50, 60 of the reference semiconductor structure 200R, the semiconductor structure 200 occupies a chip area less than that of the reference semiconductor structure 200R by about 10% to about 30%. In other words, the semiconductor structure 200 has a cell height CH1 that is less than a cell height CH2 of the reference semiconductor structure 200R by about 10% to about 30%.

In some embodiments, when the semiconductor structure 200 occupied a chip area (or a cell height) substantially equal to that of the reference semiconductor structure 200R, each of the first and second channel structures 50C, 60C in the semiconductor structure 200 may have a width in the Y direction greater than a width of each of the first and second channel structures 50C, 60C in the reference semiconductor structure 200R. This is because in the semiconductor structure 200, the first device 50, the interconnection elements (i.e., the first and second drain vias 143, 243, and the first and second drain pads 1412, 2412), and the second device 60 are displaced from each other in the Z direction, and the provision of the interconnection elements may not undesirably reduce the dimension of each of the first and second devices in the X and/or Y directions. Accordingly, the first and second devices 50, 60 in the semiconductor structure 200 may have a performance higher than that of the first and second devices 50, 60 in the reference semiconductor structure 200R by about 50% to about 70%.

Furthermore, a stack of the first and second drain pads 1412, 2412 in the semiconductor structure 200 has a dimension (for example, a height of the stack in the Z direction) less than that of the vertical interconnecting portion 35R (for example, a height of the vertical interconnecting portion 35R in the Z direction), and thus a parasitic capacitance generated between the stack of the first and second drain pads 1412, 2412 and an adjacent semiconductor structure is less than that generated between the vertical interconnecting portion 35R and an adjacent semiconductor structure.

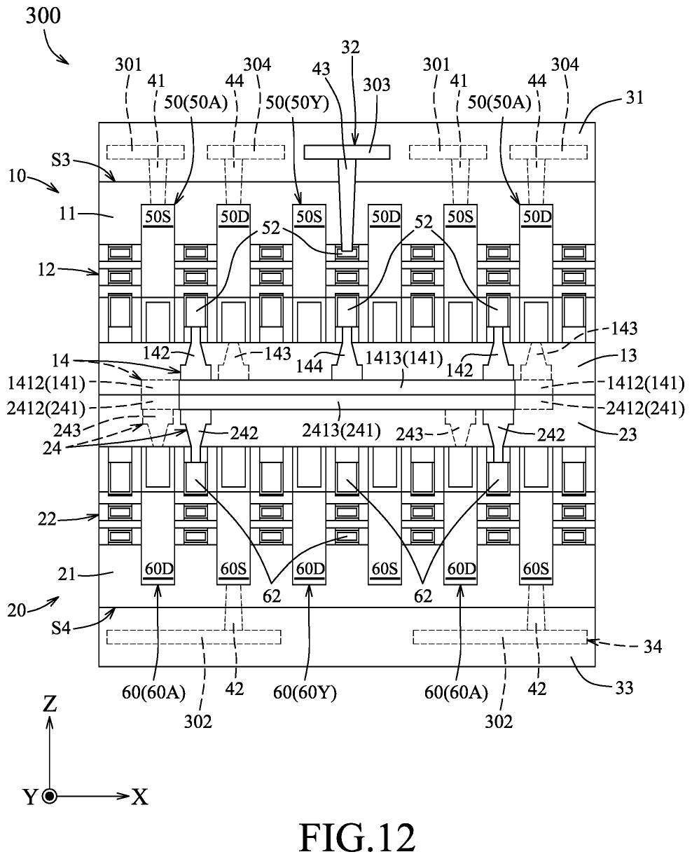

FIG. 12 illustrates a schematic sectional view of a semiconductor structure 300 in accordance with some embodiments. The semiconductor structure 300 has a structure similar to that of the semiconductor structure 200 shown in FIG. 6, but has the differences as described in the following. Some repeating structures are omitted in FIG. 12 for the sake of brevity. It is noted that similar numerals from the above-mentioned embodiments are used where appropriate, with some construction differences being indicated with different numerals.

The first main unit 12 includes a plurality of the first devices 50. FIG. 12 shows three of the first devices 50, one of which serves as a first dummy device 50Y (which may be also referred to as a first dummy portion 50Y), and the other two of which serve as first active devices 50A. The second main unit 22 includes a plurality of the second devices 60. FIG. 12 shows three of the second devices 60, one of which serves as a second dummy device 60Y (which may be also referred to as a second dummy portion 60Y), and the other two of which serve as second active devices 60A. The number of the first and second devices 50, 60 may vary according to the design of circuit layout of the semiconductor structure 300. In some embodiments, as shown in FIG. 12, the first dummy device 50Y is disposed between the first active devices 50A, and the second dummy device 60Y is disposed between the second active devices 60A, but it not limited to. In some not shown embodiments, the first dummy device 50Y (or the second dummy device 60Y) may be placed at one side of the first main unit 12 (or the second main unit 22), and the first active devices 50A (or the second active devices 60A) may be placed at the other side of the first main unit 12 (or the second main unit 22).

The semiconductor structure 300 includes a single input via 43, a plurality of the first power vias 41 (two of which are shown in FIG. 12), a plurality of the second power vias 42 (two of which are shown in FIG. 12), and a plurality of the output vias 44 (two of which are shown in FIG. 12).

The first electrically conducive feature 32 includes a single third track 303, a plurality of the first tracks 301, and a plurality of the fourth tracks 304. Each of the first tracks 301 is electrically connected to the first source feature 50S of a corresponding one of the first active devices 50A through a corresponding one of the first power vias 41. Each of the fourth tracks 304 is electrically connected to the first drain feature 50D of a corresponding one of the first active devices 50A through a corresponding one of the output vias 44. The second electrically conductive feature 34 includes a plurality of the second tracks 302 each of which is electrically connected to the second source feature 60S of a corresponding one of the second active devices 60A through a corresponding one of the second power vias 42.

In some embodiments, the input via 43 extends from the third track 303 of the first electrically conductive feature 32 into the first substrate 11 to reach the first gate electrode 52 of the first dummy device 50Y.

In some embodiments, as shown in FIG. 12, a first interconnecting pad 1413 is used to replace the first gate pad 1411 shown in FIG. 6, and a second interconnecting pad 2413 is used to replace the second gate pad 2411 shown in FIG. 6.

In addition to first active vias (for example, but not limited to, the first gate vias 142 and/or the first drain vias 143), the first electrically conductive routing 14 further includes a connecting via 144 extending to electrically connect the first gate electrode 52 of the first dummy device 50Y to the first interconnecting pad 1413. In some embodiments, at least one of the first active vias extends to electrically connect a corresponding one of the first active devices 50A to the first interconnecting pad 1413; and at least one of second active vias (for example, but not limited to, the second gate vias 242 and/or the second drain vias 243) extends to electrically connect a corresponding one of the second active devices 60A to the second interconnecting pad 2413. The first and second interconnecting pads 1413, 2413 are in direct contact with each other, so as to permit an input signal from the input via 43 to be transmitted to the first and second active devices 50A, 60A.

In some other embodiments, an alternative input via (not shown) may extend from the second electrically conductive feature 34 into the second substrate 21 to reach the second gate electrode 62 of the second dummy device 60Y. In this case, the connecting via 144 extends to electrically connect the second gate electrode 62 of the second dummy device 60Y to the second interconnecting pad 2413.

In some embodiments, as shown in FIG. 12, the first gate vias 142 (serving as the first active vias) extend respectively from the first gate electrodes 52 of the first active devices 50A to the first interconnecting pad 1413, the second gate vias 242 (serving as the second active vias) extend respectively from the second gate electrodes 62 of the second active devices 60A to the second interconnecting pad 2413. As such, the input signal from the input via 43 may be transmitted to the first gate electrodes 52 of the first active devices 50A and the second gate electrodes 62 of the second active devices 60A. In some embodiments, as shown in FIG. 12, the first drain feature 50D of each of the first active devices 50A is electrically connected to the second drain feature 60D of a corresponding one of the second active devices 60A through the first and second drain vias 143, 243 and the first and second drain pads 1412, 2412 in a manner similar to those described with reference to FIG. 7.

In some other embodiments, for example, an alternative first drain via (not shown, serving as the first active via) extends from the first drain feature 50D of at least one of the first active devices 50A to the first interconnecting pad 1413, and an alternative second drain via (not shown, serving as the second active via) extends from the second drain feature 60D of a corresponding one of the second active devices 60A which is disposed aligned with the at least one of the first active devices 50A in the Z direction. As such, the input signal from the input via 43 may be transmitted to the first drain feature 50D of the at least one of the first active devices 50A and the second drain feature 60D of the corresponding one of the second active devices 60A.

It is noted that the position of the input via 43 can be varied according to a layout design of the input via 43, the connecting via 144, the first interconnecting pad 1413, the second interconnecting pad 2413, the first active via(s), and the second active via(s), so as to permit the input signal to be transmitted to the gate electrodes 52, 62, the source features 50S, 60S or the drain features 50D, 60D. Furthermore, the first interconnecting pad 1413 is spaced apart from the first drain pad 1412 in the Y direction, and the second interconnecting pad 2413 is spaced apart from the second drain pad 2412 in the Y direction. In addition, since the first and second active devices 50A, 60A can be electrically connected to each other through the first and second electrically conductive routings 14, 24 which are disposed between the first and second main units 12, 22, the chip area of the semiconductor structure 300 is less likely to increase due to the provision of the first and second electrically conductive routings 14, 24. In addition, the input signal can be transmitted to the first and second electrically conductive routings 14, 24 through one of the first and second dummy devices 50Y, 60Y.

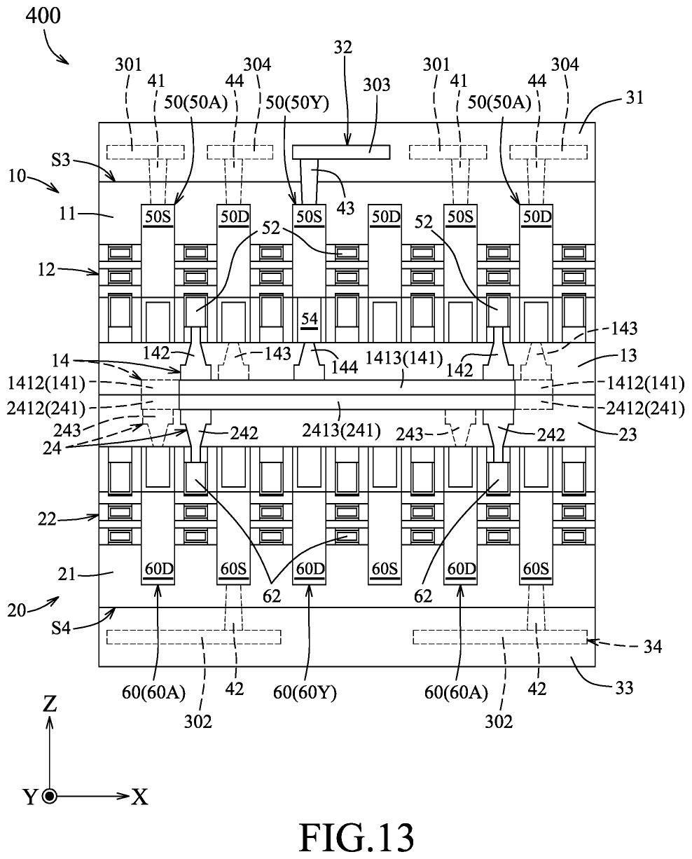

FIG. 13 illustrates a schematic sectional view of a semiconductor structure 400 in accordance with some embodiments. The semiconductor structure 400 has a structure similar to that of the semiconductor structure 300 shown in FIG. 12, but an input signal is input from one of the first source feature 50S and the first drain feature 50D of the first dummy device 50Y. Some repeating structures are omitted in FIG. 13 for the sake of brevity. It is noted that similar numerals from the above-mentioned embodiments are used where appropriate.

In some embodiments, the input via 43 extends from the third track 303 of the first electrically conductive feature 32 into the first substrate 11 to reach one of the first source feature 50S and the first drain feature 50D of the first dummy device 50Y. The connecting via 144 extends to electrically connect the one of the first source feature 50S and the first drain feature 50D of the first dummy device 50Y to the first interconnecting pad 1413. In some other embodiments, an alternative input via (not shown) may extend from the second electrically conductive feature 34 into the second substrate 21 to reach one of the second source feature 60S and the second drain feature 60D of the second dummy device 60Y. In this case, the connecting via 144 extends to electrically connect the one of the second source feature 60S and the second drain feature 60D of the second dummy device 60Y to the second interconnecting pad 2413.

In FIG. 13, the input via 43 is exemplified to reach the first source feature 50S of the first dummy device 50Y, and the connecting via 144 extends to electrically connect the first source feature 50S of the first dummy device 50Y to the first interconnecting pad 1413.

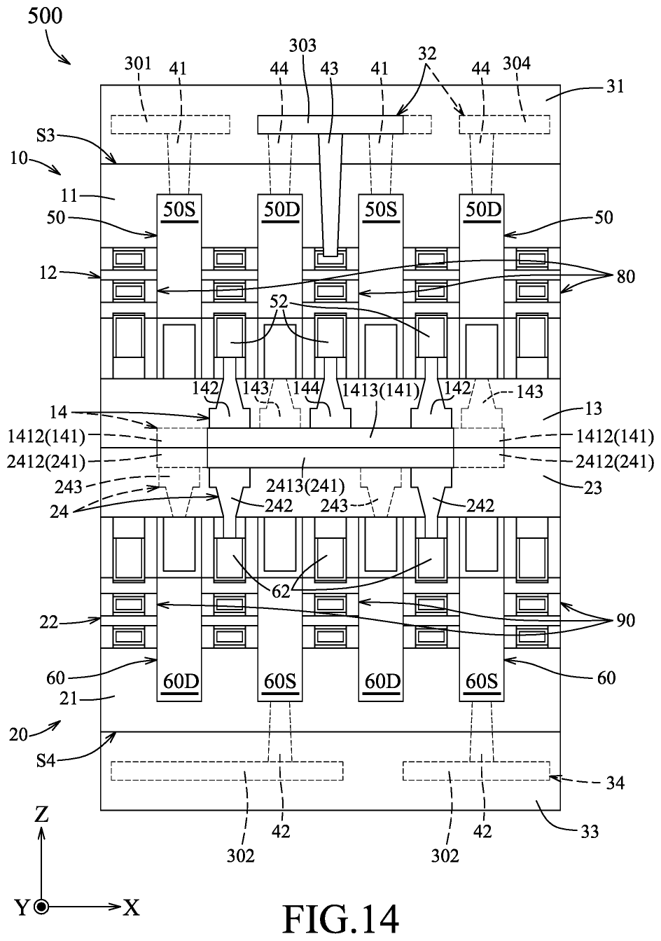

FIG. 14 illustrates a schematic sectional view of a semiconductor structure 500 in accordance with some embodiments. The semiconductor structure 500 has a structure similar to that of the semiconductor structure 300, but has the differences as described in the following. Some repeating structures are omitted in FIG. 14 for the sake of brevity. It is noted that similar numerals from the above-mentioned embodiments are used where appropriate.

Each of the first and second devices 50, 60 serves as an active device. In some embodiments, the semiconductor structure 500 includes a plurality of the first dummy portions 80, each of which is disposed between two adjacent ones of the first devices 50, and a plurality of the second dummy portions 90, each of which is disposed between two adjacent ones of the second devices 60.

In some embodiments, as shown in FIG. 14, the input via 43 extends from the third track 303 of the first electrically conductive feature 32 into the first substrate 11 to reach an electrically conductive portion (e.g., the first gate electrode 52) of one of the first dummy portions 80, and the connecting via 144 extends to electrically connect the first gate electrode 52 of the one of the first dummy portions 80 to the first interconnecting pad 1413. In some other embodiments, an alternative input via (not shown) may extend into the second substrate 21 from the second outer surface S4 to reach an electrically conductive portion (e.g., the second gate electrode 62) of one of the second dummy portions 90, and the connecting via 144 extends to electrically connect the second gate electrode 62 of the one of the second dummy portions 90 to the second interconnecting pad 2413.

In some alternative embodiments, each of the semiconductor structures 100, 200, 300, 400, 500 may further include additional features, and/or some features present in each of the semiconductor structures 100, 200, 300, 400, 500 may be modified, replaced, or eliminated without departure from the spirit and scope of the present disclosure.

In addition, each of the first and second devices 50, 60 may be any suitable device as mentioned above, and the device type of the first device(s) 50 may be the same or different from that of the second device(s) 60. For example, in a semiconductor structure as schematically shown in FIG. 15, both of the first and second devices 50, 60 are FinFETs. In some embodiments, one of the first and second devices 50, 60 is a GAAFET, and the other one of the first and second devices 50, 60 is a FinFET. For example, in a semiconductor structure as schematically shown in FIG. 16, the first device 50 is a GAAFET, and the second device 60 is a FinFET. In some embodiments, one of the first and second devices 50, 60 is a FinFET, and the other one of the first and second devices 50, 60 is a planar FET. For example, in a semiconductor structure as schematically shown in FIG. 17, the first device 50 is a planar FET, and the second device 60 is a FinFET. In some embodiments, one of the first and second devices 50, 60 is a GAAFET, and the other one of the first and second devices 50, 60 is a planar FET. For example, in a semiconductor structure as schematically shown in FIG. 18, the first device 50 is a planar FET, and the second device 60 is a GAAFET. Similar numerals from the above-mentioned embodiments are used in FIGS. 15 to 18, and some elements (for examples, the middle, first and second electrically conductive features 35, 32, 34 shown in FIG. 1) are omitted for the sake of brevity. Since FIGS. 15 to 18 are each a schematic sectional view illustrating the semiconductor structure taken along the Y direction, isolation regions 76 for isolating fin(s) 111 of the first substrate 11 or for isolating fin(s) 211 of the second substrate 21 may be shown or not shown based on the type of the devices (for example, for the planar FET, the fins are not provided, and the isolation regions for separating two adjacent planar FETs are not shown).

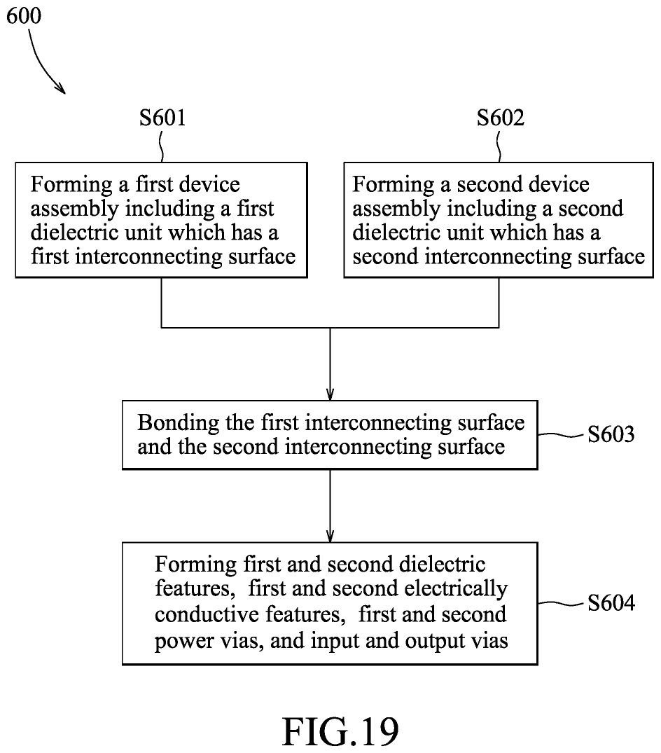

FIG. 19 is a flow diagram illustrating a method 600 for manufacturing a semiconductor structure (for example, but not limited to, the semiconductor structures 100, 200, 300, 400, 500) in accordance with some embodiments. FIGS. 16 to 19 illustrate schematic views of intermediate stages of the method 600 for manufacturing the semiconductor structure 200 in accordance with some embodiments. Some repeating structures are omitted in FIGS. 16 to 19 for the sake of brevity. It is noted that similar numerals from the above-mentioned embodiments are used where appropriate, with some construction differences being indicated with different numerals.

Referring to FIG. 19 and the examples illustrated in FIGS. 16 and 17, the method 600 begins at steps S601 and S602, where the first device assembly 10 and the second device assembly 20 are respectively and independently formed.

In some embodiments, steps S601 and S602 may be performed in a parallel manner. That is, the first and second device assemblies 10, 20 may be formed at the same time, but in different process chambers. In some other embodiments, step S601 may be performed before or after step S602 according to production planning of a factory. It is worth noting that since the first and second device assemblies 10, 20 are independently formed, each of the first and second device assemblies 10, 20 has a thermal budget which is not affected by the process sequence of steps S601 and S602.

In some other embodiments, when the second devices 60 of the second device assembly 20 are formed on the first device assembly 10, a thermal treatment during formation of the second device assembly 20 may not be performed at a relatively high temperature. In such case, if the thermal treatment for forming the second device assembly 20 is performed at a relatively high temperature, the performance of the first devices 50 of the first device assembly 10 may be undesirably affected. In comparison to aforementioned case, each of the first and second device assemblies 10, 20 in the semiconductor structures 100, 200, 300, 400, 500 may have better thermal budget control.

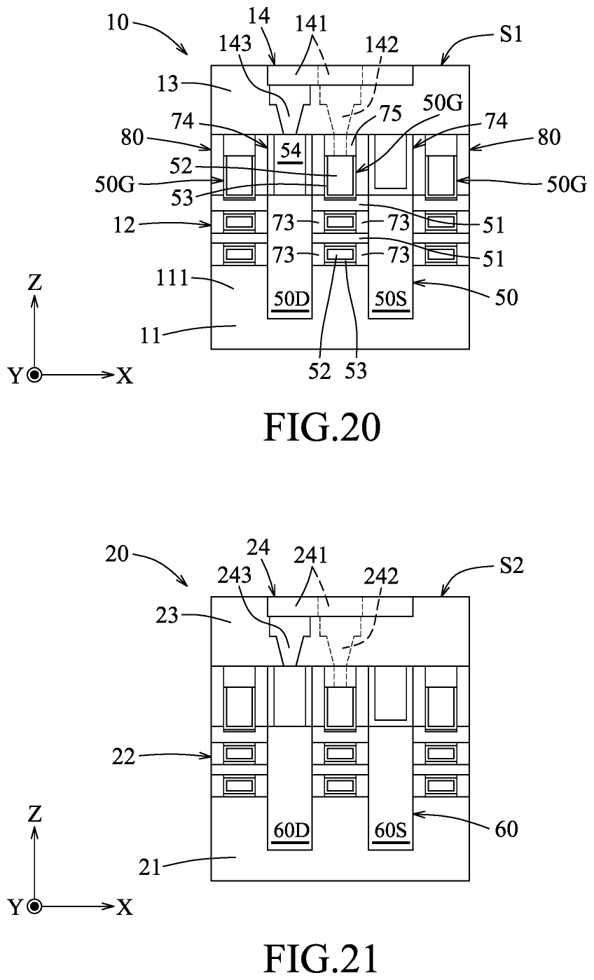

A method for manufacturing one of the first and second device assemblies 10, 20 may vary according to the configuration of a corresponding one of the first and second main units 12, 22. In some embodiments, for example, the first main unit 12 of the first device assembly 10 shown in FIG. 20 may by formed by sub-steps of: (i) patterning a semiconductor substrate and a stack (not shown) formed thereon to form a fin structure of the first substrate 11, the fin structure including a fin 111 and a stack portion (not shown) disposed on the fin 111 (the semiconductor substrate is patterned into the first substrate 11 including the fin 111, and the stack is patterned into the stack portion which including a plurality of sacrificial films and a plurality of channel films disposed to alternate with the sacrificial films in the Z direction), (ii) forming the isolation regions 76 (see FIG. 16) at two opposite sides of the fin 111 in the Y direction and that the stack portion is exposed from the isolation regions 76, (iii) forming at least three dummy gate portions (not shown) over the fin structure such that the fin structure has at least two exposed portions, which are exposed from and at two opposite sides of a middle one of the at least three dummy gate portions in the X direction, (iv) forming at least three pairs of dummy gate spacers (not shown), each pair of which are respectively formed at two opposite sides of a corresponding one of the dummy gate portions in the X direction, (v) etching the exposed portions of the fin structure to form at least two source/drain recesses (not shown), respectively, such that the channel films are respectively patterned into the channel features 51 and the sacrificial films are respectively patterned into sacrificial features (not shown), (vi) recessing the sacrificial features through the source/drain recesses to form lateral recesses (not shown), (vii) forming the inner spacers 73 respectively in the lateral recesses to cover the remaining sacrificial features, (viii) forming at least one first source feature 50S and at least one first drain feature 50D respectively in the at least two source/drain recesses, such that each of the channel features 51 (beneath the middle one of the at least three dummy gate portions) extends between the first source feature 50S and the first drain feature 50D, (ix) forming the isolation features 74 respectively on the first source feature 50S and the first drain feature 50D, (x) removing the dummy gate portions and the remaining sacrificial features using a wet etching process or other suitable processes to form at least three cavities (not shown), and (xi) sequentially depositing materials for forming the first gate electrode 52 and the first gate dielectric layer 53 to fill the cavities by a blanket deposition process, such as chemical vapor deposition (CVD), atomic layer deposition (ALD), molecular- beam deposition (MBD), molecular layer deposition (MLD), or other suitable deposition techniques, (xii) performing a planarization process, for example, but not limited to, chemical mechanical polishing (CMP), to remove excesses of the materials for forming the first gate electrode 52 and the first gate dielectric layer 53 and to expose the isolation features 74, (xiii) etching back the materials for forming the first gate electrode 52 and the first gate dielectric layer 53 using for example, but not limited to, dry etching, wet etching, other suitable processes, or combinations thereof, such that the middle one of the dummy gate portions is formed into the first gate structure 50G of the first device 50 and left and right ones of the dummy gate portions are formed into the first gate structures 50G of the first dummy portions 80, (xiv) forming the cap layer 75 on the first gate structure 50G of each of the first device 50 and the first dummy portions 80 using a blanket deposition process, such as, but not limited to, CVD, ALD, or other suitable deposition techniques, followed by a planarization process, for example, but not limited to, CMP, or other suitable processes, to expose the isolation features 74, and (xv) forming the first contact feature 54 in one of the isolation features 74 on the first drain feature 50S using a blanket deposition process, such as, but not limited to, CVD, ALD, or other suitable deposition techniques, followed by a planarization process, for example, but not limited to, CMP, or other suitable processes, to expose the isolation features 74. Afterwards, the first dielectric unit 13 is formed on the first main unit 12 and the first electrically conductive routing 14 is formed in the first dielectric unit 13 by a dual damascene process, a single damascene process, or other suitable back-end-of-line (BEOL) techniques. Thereafter, the first device assembly 10 is obtained. Other suitable processes for forming the first device assembly 10 are within the contemplated scope of the present disclosure.

In some embodiments, the second device assembly 20 shown in FIG. 21 may be formed in a manner similar to that of the first device assembly 10, and thus details thereof are omitted for the sake of brevity. Other suitable processes for forming the second device assembly 20 are within the contemplated scope of the present disclosure.

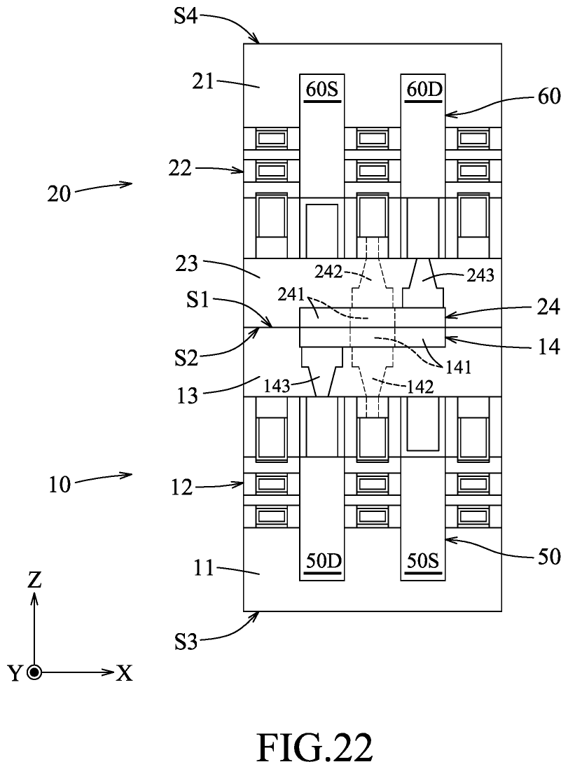

Referring to FIG. 19 and the examples illustrated in FIG. 22, the method 100 proceeds to step S603, where the first interconnecting surface S1 and the second interconnecting surface S2 are bonded to each other.

In some embodiments, during a dielectric bonding between the first interconnecting surface S1 and the second interconnecting surface S2, the first and second end portions 241 and 242 are bonded to each other by a metal bonding. Thus, step S603 may be performed by a hybrid bonding process including the dielectric bonding between the first and second dielectric units 13, 23, and the metal bonding between the first and second end portions 141, 241.

In some embodiments, step S603 may include sub-steps of: (i) aligning the first and second dielectric units 13, 23 with each other to permit the first and second end portions 141, 241 to be aligned with each other, and (ii) bonding the first and second dielectric units 13, 23 with each other to permit the first and second end portions 141, 241 to be bonded with each other. In some embodiment, the sub-step of alignment may result in the first and second end portions 141, 241 being aligned with a relatively high precision. For example, the first and second end portions 141, 241 may be aligned well with a precision less than about 10 nm (or even a few nm).

Referring to FIG. 19 and the examples illustrated in FIGS. 6 and 7, the method 100 proceeds to step S604, where the first and second dielectric features 31, 33, the first and second electrically conductive features 32, 34, the first and second power vias 41, 42, the input and output vias 43, 44 are formed, thereby obtaining the semiconductor structure 200.

In some embodiments, step S603 may include sub-steps of: (i) forming the second power via 42, the second dielectric feature 33 and the second electrically conductive feature 34 using any possible process to permit the second power via 42 to extend from the second electrically conductive feature 34 to connect an electrically conductive portion of the second device 60; (ii) bonding a carrier substrate (not shown) to a side of the second dielectric feature 33 opposite to the second device assembly 20 through a dielectric bonding; (iii) flipping the structure obtained after sub-step (ii) upside down through the carrier substrate; (iv) forming the input and output via 43, 44, the first power via 41, the first dielectric feature 31 and the first electrically conductive feature 32 using any possible process to permit each of the input and output via 43, 44 and the first power via 41 to extend from the first electrically conductive feature 32 to connect a corresponding one of electrically conductive portions of the first device 50; and (v) removing the carrier substrate.

In some embodiments, some steps in the method 600 may be modified, replaced, or eliminated without departure from the spirit and scope of the present disclosure.

In this disclosure, the first and second device assemblies are prepared in a parallel manner and are bonded to each other by a hybrid bonding to obtain the semiconductor structure, and therefore, a time period for making the semiconductor structure can be shorter. Furthermore, each of the first and second device assemblies has a normal aspect ratio and can be efficiently made. In addition, each of the first and second devices can be designed independently, and has a thermal budget that is not affected by changing sequences of process steps. It is worth noting that in the semiconductor structure of this disclosure, in addition to the first and second electrically conductive features, the middle electrically conductive feature is provided for electrically connecting the first and second main units, and thus the semiconductor structure of this disclosure allows increased freedom of circuit design (e.g., various signal input manners). Therefore, the semiconductor structure also has advantages of occupying a relatively small chip area, and having an enhanced device performance.

In accordance with some embodiments of the present disclosure, a semiconductor structure includes a first device assembly and a second device assembly. The first device assembly includes a first substrate, a first main unit disposed on the first substrate and including at least one first device, a first dielectric unit disposed on the first main unit opposite to the first substrate and having a first interconnecting surface opposite to the first substrate, and a first electrically conductive routing which is disposed in the first dielectric unit and which is electrically connected to the at least one first device. The first electrically conductive routing includes a first end portion. The second device assembly includes a second substrate, a second main unit disposed on the second substrate and including at least one second device, a second dielectric unit disposed on the second main unit opposite to the second substrate and having a second interconnecting surface which is opposite to the second substrate, and a second electrically conductive routing which is disposed in the second dielectric unit and which is electrically connected to the at least one second device. The second electrically conductive routing includes a second end portion. The first interconnecting surface is bonded to the second interconnecting surface such that the second end portion of the second electrically conductive routing is in direct contact with the first end portion of the first electrically conductive routing.

In accordance with some embodiments of the present disclosure, the first end portion of the first electrically conductive routing overlaps with the second end portion of the second electrically conductive routing.

In accordance with some embodiments of the present disclosure, the at least one first device includes a first channel structure, a first gate structure which is disposed on the first channel structure, and which includes a first gate electrode and a first gate dielectric layer disposed between the first gate electrode and the first channel structure, and a first source feature and a first drain feature which are respectively disposed at two opposite sides of the first gate structure such that the first channel structure extends between the first source feature and the first drain feature. The at least one second device includes a second channel structure, a second gate structure which is disposed on the second channel structure, and which includes a second gate electrode and a second gate dielectric layer disposed between the second gate electrode and the second channel structure, and a second source feature and a second drain feature which are respectively disposed at two opposite sides of the second gate structure such that the second channel structure extends between the second source feature and the second drain feature.

In accordance with some embodiments of the present disclosure, the first gate electrode and the second gate electrode are spaced apart from each other in a first direction. The first end portion of the first electrically conductive routing includes a first gate pad, and the second end portion of the second electrically conductive routing includes a second gate pad. The first electrically conductive routing further includes a first gate via which extends in the first direction toward the second gate electrode to terminate at the first gate pad so as to permit the first gate electrode to be electrically connected to the first gate pad through the first gate via. The second electrically conductive routing further includes a second gate via which extends in the first direction toward the first gate electrode to terminate at the second gate pad so as to permit the second gate electrode to be electrically connected to the second gate pad through the second gate via. The first and second gate pads are in direct contact with each other so as to permit the first gate electrode to be electrically connected to the second gate electrode through the first and second gate vias and the first and second gate pads.

In accordance with some embodiments of the present disclosure, the first substrate has a first outer surface opposite to the second device assembly. The semiconductor structure further includes an input via extending into the first substrate from the first outer surface to reach the first gate electrode of the at least one first device so as to permit an input signal from the input via to be transmitted to the at least one first device.

In accordance with some embodiments of the present disclosure, the first and second drain features are spaced apart from each other in a first direction. The first and second source features are spaced apart from each other in the first direction. The first end portion of the first electrically conductive routing includes a first drain pad, and the second end portion of the second electrically conductive routing includes a second drain pad. The first electrically conductive routing further includes a first drain via which extends in the first direction toward the second drain feature to terminate at the first drain pad so as to permit the first drain feature to be electrically connected to the first drain pad through the first drain via. The second electrically conductive routing further includes a second drain via which extends in the first direction toward the first drain feature to terminate at the second drain pad so as to permit the second drain feature to be electrically connected to the second drain pad through the second drain via. The first and second drain pads are in direct contact with each other so as to permit the first drain feature to be electrically connected to the second drain feature through the first and second drain vias and the first and second drain pads.

In accordance with some embodiments of the present disclosure, the second substrate has a second outer surface opposite to the first device assembly. The semiconductor structure further includes an output via extending into the first substrate from the first outer surface to reach the first drain feature of the at least one first device so as to permit an output signal in response to the input signal to be output through the output via, a first power via extending into the first substrate from the first outer surface to reach the first source feature of the at least one first device so as to permit a first voltage to be applied to the first source feature of the at least one first device through the first power via, and a second power via extending into the second substrate from the second outer surface to reach the second source feature of the at least one second device so as to permit a second voltage to be applied to the second source feature of the at least one second device through the second power via.

In accordance with some embodiments of the present disclosure, the first drain feature and the second source feature are spaced apart from each other in a first direction. The first source feature and the second drain feature are spaced apart from each other in the first direction. The first end portion of the first electrically conductive routing includes a first drain pad, and the second end portion of the second electrically conductive routing includes a second drain pad. The first electrically conductive routing further includes a first drain via which extends in the first direction toward the second source feature to terminate at the first drain pad so as to permit the first drain feature to be electrically connected to the first drain pad through the first drain via. The second electrically conductive routing further includes a second drain via which extends in the first direction toward the first source feature to terminate at the second drain pad so as to permit the second drain feature to be electrically connected to the second drain pad through the second drain via. The first and second drain pads are in direct contact with each other so as to permit the first drain feature to be electrically connected to the second drain feature through the first and second drain vias and the first and second drain pads.

In accordance with some embodiments of the present disclosure, the first source feature and first drain feature are opposite to each other in a second direction transverse to the first direction. The second source feature and the second drain feature are opposite to each other in the second direction. The first gate structure has a first gate width in the second direction. The second gate structure has a second gate width in the second direction. Each of the first and second drain pads has a pad width in the second direction which is not less than each of the first and second gate widths.

In accordance with some embodiments of the present disclosure, the first gate electrode and the second gate electrode are spaced apart from each other in the first direction. The first end portion of the first electrically conductive routing further includes a first gate pad, and the second end portion of the second electrically conductive routing further includes a second gate pad. The first electrically conductive routing further includes a first gate via which extends in the first direction toward the second gate electrode to terminate at the first gate pad so as to permit the first gate electrode to be electrically connected to the first gate pad through the first gate via. The second electrically conductive routing further includes a second gate via which extends in the first direction toward the first gate electrode to terminate at the second gate pad so as to permit the second gate electrode to be electrically connected to the second gate pad through the second gate via. The first and second gate pads are in direct contact with each other so as to permit the first gate electrode to be electrically connected to the second gate electrode through the first and second gate vias and the first and second gate pads. The first drain pad is spaced apart from the first gate pad in a third direction transverse to the first and second directions. The second drain pad is spaced apart from the second gate pad in the third direction.

In accordance with some embodiments of the present disclosure, the first main unit includes two of the first devices, one of which serves as a first dummy device, and the other of which serves as a first active device. The second main unit includes two of the second devices, one of which serves as a second dummy device, and the other of which serves as a second active device. The first substrate has a first outer surface opposite to the second device assembly. The semiconductor structure further includes an input via extending into the first substrate from the first outer surface to reach the first gate electrode of the first dummy device. The first end portion of the first electrically conductive routing includes a first interconnecting pad, and the second end portion of the second electrically conductive routing includes a second interconnecting pad. The first electrically conductive routing further includes a connecting via extending to electrically connect the first gate electrode of the first dummy device to the first interconnecting pad, and a first active via extending to electrically connect the first active device to the first interconnecting pad. The second electrically conductive routing further includes a second active via extending to electrically connect the second active device to the second interconnecting pad. The first and second interconnecting pads are in direct contact with each other so as to permit an input signal from the input via to be transmitted to the first and second active devices.

In accordance with some embodiments of the present disclosure, the first active via extends to electrically connect the first gate electrode of the first active device to the first interconnecting pad, and the second active via extends to electrically connect the second gate electrode of the second active device to the second interconnecting pad.

In accordance with some embodiments of the present disclosure, the first main unit includes two of the first devices, one of which serves as a first dummy device, and the other of which serves as a first active device. The second main unit includes two of the second devices, one of which serves as a second dummy device, and the other of which serves as a second active device. The first substrate has a first outer surface opposite to the second device assembly. The semiconductor structure further includes an input via extending into the first substrate from the first outer surface to reach one of the first source feature and the first drain feature of the first dummy device. The first end portion of the first electrically conductive routing includes a first interconnecting pad, and the second end portion of the second electrically conductive routing includes a second interconnecting pad. The first electrically conductive routing further includes a connecting via extending to electrically connect the one of the first source feature and the first drain feature of the first dummy device to the first interconnecting pad, and a first active via extending to electrically connect the first active device to the first interconnecting pad. The second electrically conductive routing further includes a second active via extending to electrically connect the second active device to the second interconnecting pad. The first and second interconnecting pads are in direct contact with each other so as to permit an input signal from the input via to be transmitted to the first and second active devices.

In accordance with some embodiments of the present disclosure, a semiconductor structure includes a first device assembly and a second device assembly. The first device assembly includes a first substrate, a first main unit disposed on the first substrate and including a first dummy portion and at least one first device, a first dielectric unit disposed on the first main unit opposite to the first substrate and having a first interconnecting surface opposite to the first substrate, and a first electrically conductive routing which is disposed in the first dielectric unit and which is electrically connected to the first main unit. The first electrically conductive routing includes a first end portion opposite to the first substrate. The second device assembly includes a second substrate, a second main unit disposed on the second substrate and including a second dummy portion and at least one second device, a second dielectric unit disposed on the second main unit opposite to the second substrate and having a second interconnecting surface which is opposite to the second substrate, and a second electrically conductive routing which is disposed in the second dielectric unit and which is electrically connected to the second main unit. The second electrically conductive routing includes a second end portion opposite to the second substrate. The first interconnecting surface is bonded to the second interconnecting surface such that the second end portion of the second electrically conductive routing is in direct contact with the first end portion of the first electrically conductive routing.

In accordance with some embodiments of the present disclosure, the first main unit includes a plurality of the first devices, and the second main unit includes a plurality of the second devices. Each of the first and second devices includes a channel structure, a gate structure which is disposed on the channel structure, and which includes a gate electrode and a gate dielectric layer disposed between the gate electrode and the channel structure, and a source feature and a drain feature which are respectively disposed at two opposite sides of the gate structure such that the channel structure extends between the source feature and the drain feature. The first substrate has a first outer surface opposite to the second device assembly. The semiconductor structure further includes an input via extending into the first substrate from the first outer surface to reach the first dummy portion. The first end portion of the first electrically conductive routing includes a first interconnecting pad, and the second end portion of the second electrically conductive routing includes a second interconnecting pad. The first electrically conductive routing further includes a connecting via extending to electrically connect the first dummy portion to the first interconnecting pad, and a plurality of first active vias extending from the interconnecting pad to be electrically connected to the first devices, respectively. The second electrically conductive routing further includes a plurality of second active vias extending from the second interconnecting pad to be electrically connected to the second devices, respectively. The first and second interconnecting pads are in direct contact with each other so as to permit an input signal from the input via to be transmitted to the first and second devices.

In accordance with some embodiments of the present disclosure, the input via extends to reach an electrically conductive portion of the first dummy portion. The connecting via extends to electrically connect the electrically conductive portion of the first dummy portion to the first interconnecting pad. Each of the first active vias is electrically connected to one of the gate electrode, the drain feature and the source feature of a corresponding one of the first devices. Each of the second active vias is electrically connected to one of the gate electrode, the drain feature and the source feature of a corresponding one of the second devices.

In accordance with some embodiments of the present disclosure, a method for forming a semiconductor structure includes: forming a first device assembly which includes a first substrate, a first main unit disposed on the first substrate and including at least one first device, a first dielectric unit disposed on the first main unit opposite to the first substrate and having a first interconnecting surface opposite to the first substrate, and a first electrically conductive routing which is disposed in the first dielectric unit and which is electrically connected to the at least one first device, the first electrically conductive routing including a first end portion which is exposed from the first interconnecting surface; forming a second device assembly which includes a second substrate, a second main unit disposed on the second substrate and including at least one second device, a second dielectric unit disposed on the second main unit opposite to the second substrate and having a second interconnecting surface which is opposite to the second substrate, and a second electrically conductive routing which is disposed in the second dielectric unit and which is electrically connected to the at least one second device, the second electrically conductive routing including a second end portion which is exposed from the second interconnecting surface; and bonding the first interconnecting surface and the second interconnecting surface to each other, so as to bring the first end portion of the first electrically conductive routing into a direct contact with the second end portion of the second electrically conductive routing.

In accordance with some embodiments of the present disclosure, the first and second interconnecting surfaces are bonded to each other by dielectric bonding. The first electrically conductive routing and the second electrically conductive routing are each made of a metal material such that during dielectric bonding of the first and second interconnecting surfaces, the first and second end portions are bonded to each other by metal bonding.

In accordance with some embodiments of the present disclosure, forming the first device assembly and forming the second device assembly are performed in a parallel manner.

In accordance with some embodiments of the present disclosure, during bonding of the first and second interconnecting surfaces, the first end portion of the first electrically conductive routing is brought into alignment with the second end portion of the second electrically conductive routing so as to permit the first end portion to be in direct contact with the second end portion.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first device assembly including
a first substrate,
a first main unit disposed on the first substrate and including at least one first device,
a first dielectric unit disposed on the first main unit opposite to the first substrate and having a first interconnecting surface opposite to the first substrate, and
a first electrically conductive routing which is disposed in the first dielectric unit and which is electrically connected to the at least one first device, the first electrically conductive routing including a first end portion; and
a second device assembly including
a second substrate,
a second main unit disposed on the second substrate and including at least one second device,
a second dielectric unit disposed on the second main unit opposite to the second substrate and having a second interconnecting surface which is opposite to the second substrate, and
a second electrically conductive routing which is disposed in the second dielectric unit and which is electrically connected to the at least one second device, the second electrically conductive routing including a second end portion, the first interconnecting surface being bonded to the second interconnecting surface such that the second end portion of the second electrically conductive routing is in direct contact with the first end portion of the first electrically conductive routing.

2. The semiconductor structure of claim 1, wherein
the first end portion of the first electrically conductive routing overlaps with the second end portion of the second electrically conductive routing.

3. The semiconductor structure of claim 1, wherein:
the at least one first device includes
a first channel structure,
a first gate structure which is disposed on the first channel structure, and which includes a first gate electrode and a first gate dielectric layer disposed between the first gate electrode and the first channel structure, and
a first source feature and a first drain feature which are respectively disposed at two opposite sides of the first gate structure such that the first channel structure extends between the first source feature and the first drain feature; and
the at least one second device includes
a second channel structure,
a second gate structure which is disposed on the second channel structure, and which includes a second gate electrode and a second gate dielectric layer disposed between the second gate electrode and the second channel structure, and
a second source feature and a second drain feature which are respectively disposed at two opposite sides of the second gate structure such that the second channel structure extends between the second source feature and the second drain feature.

4. The semiconductor structure of claim 3, wherein:
the first gate electrode and the second gate electrode are spaced apart from each other in a first direction;
the first end portion of the first electrically conductive routing includes a first gate pad, and the second end portion of the second electrically conductive routing includes a second gate pad;
the first electrically conductive routing further includes a first gate via which extends in the first direction toward the second gate electrode to terminate at the first gate pad so as to permit the first gate electrode to be electrically connected to the first gate pad through the first gate via;
the second electrically conductive routing further includes a second gate via which extends in the first direction toward the first gate electrode to terminate at the second gate pad so as to permit the second gate electrode to be electrically connected to the second gate pad through the second gate via; and
the first and second gate pads are in direct contact with each other so as to permit the first gate electrode to be electrically connected to the second gate electrode through the first and second gate vias and the first and second gate pads.

5. The semiconductor structure of claim 4, wherein:
the first substrate has a first outer surface opposite to the second device assembly; and
the semiconductor structure further includes an input via extending into the first substrate from the first outer surface to reach the first gate electrode of the at least one first device so as to permit an input signal from the input via to be transmitted to the at least one first device.

6. The semiconductor structure of claim 5, wherein:
the first and second drain features are spaced apart from each other in a first direction;
the first and second source features are spaced apart from each other in the first direction;
the first end portion of the first electrically conductive routing includes a first drain pad, and the second end portion of the second electrically conductive routing includes a second drain pad;
the first electrically conductive routing further includes a first drain via which extends in the first direction toward the second drain feature to terminate at the first drain pad so as to permit the first drain feature to be electrically connected to the first drain pad through the first drain via;
the second electrically conductive routing further includes a second drain via which extends in the first direction toward the first drain feature to terminate at the second drain pad so as to permit the second drain feature to be electrically connected to the second drain pad through the second drain via; and
the first and second drain pads are in direct contact with each other so as to permit the first drain feature to be electrically connected to the second drain feature through the first and second drain vias and the first and second drain pads.

7. The semiconductor structure of claim 6, wherein:
the second substrate has a second outer surface opposite to the first device assembly; and
the semiconductor structure further includes
an output via extending into the first substrate from the first outer surface to reach the first drain feature of the at least one first device so as to permit an output signal in response to the input signal to be output through the output via,
a first power via extending into the first substrate from the first outer surface to reach the first source feature of the at least one first device so as to permit a first voltage to be applied to the first source feature of the at least one first device through the first power via, and
a second power via extending into the second substrate from the second outer surface to reach the second source feature of the at least one second device so as to permit a second voltage to be applied to the second source feature of the at least one second device through the second power via.

8. The semiconductor structure of claim 3, wherein:
the first drain feature and the second source feature are spaced apart from each other in a first direction;
the first source feature and the second drain feature are spaced apart from each other in the first direction;
the first end portion of the first electrically conductive routing includes a first drain pad, and the second end portion of the second electrically conductive routing includes a second drain pad;
the first electrically conductive routing further includes a first drain via which extends in the first direction toward the second source feature to terminate at the first drain pad so as to permit the first drain feature to be electrically connected to the first drain pad through the first drain via;
the second electrically conductive routing further includes a second drain via which extends in the first direction toward the first source feature to terminate at the second drain pad so as to permit the second drain feature to be electrically connected to the second drain pad through the second drain via; and
the first and second drain pads are in direct contact with each other so as to permit the first drain feature to be electrically connected to the second drain feature through the first and second drain vias and the first and second drain pads.

9. The semiconductor structure of claim 8, wherein:
the first source feature and first drain feature are opposite to each other in a second direction transverse to the first direction;
the second source feature and the second drain feature are opposite to each other in the second direction;
the first gate structure has a first gate width in the second direction;
the second gate structure has a second gate width in the second direction; and
each of the first and second drain pads has a pad width in the second direction which is not less than each of the first and second gate widths.

10. The semiconductor structure of claim 8, wherein:
the first gate electrode and the second gate electrode are spaced apart from each other in the first direction;
the first end portion of the first electrically conductive routing further includes a first gate pad, and the second end portion of the second electrically conductive routing further includes a second gate pad;
the first electrically conductive routing further includes a first gate via which extends in the first direction toward the second gate electrode to terminate at the first gate pad so as to permit the first gate electrode to be electrically connected to the first gate pad through the first gate via;
the second electrically conductive routing further includes a second gate via which extends in the first direction toward the first gate electrode to terminate at the second gate pad so as to permit the second gate electrode to be electrically connected to the second gate pad through the second gate via;
the first and second gate pads are in direct contact with each other so as to permit the first gate electrode to be electrically connected to the second gate electrode through the first and second gate vias and the first and second gate pads;
the first drain pad is spaced apart from the first gate pad in a third direction transverse to the first and second directions; and
the second drain pad is spaced apart from the second gate pad in the third direction.

11. The semiconductor structure of claim 3, wherein:
the first main unit includes two of the first devices, one of which serves as a first dummy device, and the other of which serves as a first active device;
the second main unit includes two of the second devices, one of which serves as a second dummy device, and the other of which serves as a second active device;
the first substrate has a first outer surface opposite to the second device assembly;
the semiconductor structure further includes an input via extending into the first substrate from the first outer surface to reach the first gate electrode of the first dummy device;
the first end portion of the first electrically conductive routing includes a first interconnecting pad, and the second end portion of the second electrically conductive routing includes a second interconnecting pad;
the first electrically conductive routing further includes
a connecting via extending to electrically connect the first gate electrode of the first dummy device to the first interconnecting pad, and
a first active via extending to electrically connect the first active device to the first interconnecting pad;
the second electrically conductive routing further includes
a second active via extending to electrically connect the second active device to the second interconnecting pad; and
the first and second interconnecting pads are in direct contact with each other so as to permit an input signal from the input via to be transmitted to the first and second active devices.

12. The semiconductor structure of claim 11, wherein
the first active via extends to electrically connect the first gate electrode of the first active device to the first interconnecting pad, and
the second active via extends to electrically connect the second gate electrode of the second active device to the second interconnecting pad.

13. The semiconductor structure of claim 3, wherein:
the first main unit includes two of the first devices, one of which serves as a first dummy device, and the other of which serves as a first active device;
the second main unit includes two of the second devices, one of which serves as a second dummy device, and the other of which serves as a second active device;
the first substrate has a first outer surface opposite to the second device assembly;
the semiconductor structure further includes an input via extending into the first substrate from the first outer surface to reach one of the first source feature and the first drain feature of the first dummy device;
the first end portion of the first electrically conductive routing includes a first interconnecting pad, and the second end portion of the second electrically conductive routing includes a second interconnecting pad;
the first electrically conductive routing further includes
a connecting via extending to electrically connect the one of the first source feature and the first drain feature of the first dummy device to the first interconnecting pad, and
a first active via extending to electrically connect the first active device to the first interconnecting pad;
the second electrically conductive routing further includes
a second active via extending to electrically connect the second active device to the second interconnecting pad; and
the first and second interconnecting pads are in direct contact with each other so as to permit an input signal from the input via to be transmitted to the first and second active devices.

14. A semiconductor structure, comprising:
a first device assembly including
a first substrate,
a first main unit disposed on the first substrate and including a first dummy portion and at least one first device,
a first dielectric unit disposed on the first main unit opposite to the first substrate and having a first interconnecting surface opposite to the first substrate, and
a first electrically conductive routing which is disposed in the first dielectric unit and which is electrically connected to the first main unit, the first electrically conductive routing including a first end portion opposite to the first substrate; and
a second device assembly including
a second substrate,
a second main unit disposed on the second substrate and including a second dummy portion and at least one second device,
a second dielectric unit disposed on the second main unit opposite to the second substrate and having a second interconnecting surface which is opposite to the second substrate, and
a second electrically conductive routing which is disposed in the second dielectric unit and which is electrically connected to the second main unit, the second electrically conductive routing including a second end portion opposite to the second substrate, the first interconnecting surface being bonded to the second interconnecting surface such that the second end portion of the second electrically conductive routing is in direct contact with the first end portion of the first electrically conductive routing.

15. The semiconductor structure of claim 14, wherein:
the first main unit includes a plurality of the first devices, and the second main unit includes a plurality of the second devices;
each of the first and second devices includes
a channel structure,
a gate structure which is disposed on the channel structure, and which includes a gate electrode and a gate dielectric layer disposed between the gate electrode and the channel structure, and
a source feature and a drain feature which are respectively disposed at two opposite sides of the gate structure such that the channel structure extends between the source feature and the drain feature;
the first substrate has a first outer surface opposite to the second device assembly;
the semiconductor structure further includes an input via extending into the first substrate from the first outer surface to reach the first dummy portion;
the first end portion of the first electrically conductive routing includes a first interconnecting pad, and the second end portion of the second electrically conductive routing includes a second interconnecting pad;
the first electrically conductive routing further includes
a connecting via extending to electrically connect the first dummy portion to the first interconnecting pad, and
a plurality of first active vias extending from the interconnecting pad to be electrically connected to the first devices, respectively;
the second electrically conductive routing further includes
a plurality of second active vias extending from the second interconnecting pad to be electrically connected to the second devices, respectively; and
the first and second interconnecting pads are in direct contact with each other so as to permit an input signal from the input via to be transmitted to the first and second devices.

16. The semiconductor structure of claim 15, wherein:
the input via extends to reach an electrically conductive portion of the first dummy portion;
the connecting via extends to electrically connect the electrically conductive portion of the first dummy portion to the first interconnecting pad;
each of the first active vias is electrically connected to one of the gate electrode, the drain feature and the source feature of a corresponding one of the first devices; and
each of the second active vias is electrically connected to one of the gate electrode, the drain feature and the source feature of a corresponding one of the second devices.

17. A method for forming a semiconductor structure, comprising:
forming a first device assembly which includes
a first substrate,
a first main unit disposed on the first substrate and including at least one first device,
a first dielectric unit disposed on the first main unit opposite to the first substrate and having a first interconnecting surface opposite to the first substrate, and
a first electrically conductive routing which is disposed in the first dielectric unit and which is electrically connected to the at least one first device, the first electrically conductive routing including a first end portion which is exposed from the first interconnecting surface;
forming a second device assembly which includes
a second substrate,
a second main unit disposed on the second substrate and including at least one second device,
a second dielectric unit disposed on the second main unit opposite to the second substrate and having a second interconnecting surface which is opposite to the second substrate, and
a second electrically conductive routing which is disposed in the second dielectric unit and which is electrically connected to the at least one second device, the second electrically conductive routing including a second end portion which is exposed from the second interconnecting surface; and
bonding the first interconnecting surface and the second interconnecting surface to each other, so as to bring the first end portion of the first electrically conductive routing into a direct contact with the second end portion of the second electrically conductive routing.

18. The method of claim 17, wherein:
the first and second interconnecting surfaces are bonded to each other by dielectric bonding; and
the first electrically conductive routing and the second electrically conductive routing are each made of a metal material such that during dielectric bonding of the first and second interconnecting surfaces, the first and second end portions are bonded to each other by metal bonding.

19. The method of claim 17, wherein forming the first device assembly and forming the second device assembly are performed in a parallel manner.

20. The method of claim 17, wherein during bonding of the first and second interconnecting surfaces, the first end portion of the first electrically conductive routing is brought into alignment with the second end portion of the second electrically conductive routing so as to permit the first end portion to be in direct contact with the second end portion.
